(19) United States
(12) Patent Application Publication
(10) Pub. No.: US 2025/0372563 A1
(43) Pub. Date: Dec. 4, 2025

(54) CURABLE COMPOSITION FOR FORMING ADHESIVE STRUCTURE, ADHESIVE STRUCTURE, METHOD OF MANUFACTURING ADHESIVE STRUCTURE, AND SEMICONDUCTOR DEVICE

(71) Applicants: Tohru YASHIRO, Kanagawa (JP); Takeshi ENDOH, Kanagawa (JP); Fuminari KANEKO, Kanagawa (JP); Yuto MATSUOKA, Tokyo (JP); Noriyuki KIYONAGA, Kanagawa (JP); Tomoaki SUGAWARA, Kanagawa (JP); Naoki URA, Kanagawa (JP); Naru TANAKA, Chiba (JP); Kazuaki TSUJI, Tokyo (JP)

(72) Inventors: Tohru YASHIRO, Kanagawa (JP); Takeshi ENDOH, Kanagawa (JP); Fuminari KANEKO, Kanagawa (JP); Yuto MATSUOKA, Tokyo (JP); Noriyuki KIYONAGA, Kanagawa (JP); Tomoaki SUGAWARA, Kanagawa (JP); Naoki URA, Kanagawa (JP); Naru TANAKA, Chiba (JP); Kazuaki TSUJI, Tokyo (JP)

(21) Appl. No.: 18/874,596

(22) PCT Filed: Jun. 16, 2023
(86) PCT No.: PCT/IB2023/056239

§ 371 Date: Dec. 13, 2024

(30) Foreign Application Priority Data
Jun. 17, 2022 (JP) 2022-097962
Apr. 19, 2023 (JP) 2023-068473

(51) Int. Cl. H01L 23/00; C09J 11/04; C09J 11/06; C09J 163/00; H01L 23/373

(52) U.S. Cl. CPC H01L 24/29; C09J 11/04; C09J 11/06; C09J 163/00; H01L 23/3737; H01L 24/26; H01L 24/27; H01L 24/32; H01L 2224/26145; H01L 2224/26175; H01L 2224/27013; H01L 2224/2732; H01L 2224/27515; H01L 2224/2919; H01L 2224/3201; H01L 2224/32053; H01L 2224/32056; H01L 2224/32058; H01L 2224/32059; H01L 2224/3207; H01L 2224/32145; H01L 2224/32225; H01L 2924/07811; H01L 2924/35121

(57) ABSTRACT

Provided is a curable composition for forming an adhesive structure that can be discharged by an inkjet printing method and includes a glycidylamine-type epoxy compound, an oxetane compound, and a cationic polymerization initiator. In the curable composition for forming an adhesive structure, a proportion of the glycidylamine-type epoxy compound is 10% by mass or more.

### TECHNICAL FIELD

The present disclosure relates to a curable composition for forming an adhesive structure, an adhesive structure, a method of manufacturing the adhesive structure, and a semiconductor device.

### BACKGROUND ART

As electronic circuit boards are more highly integrated and operate at higher speeds, electronic circuit boards are subjected to an increase in temperature due to heat-generating components such as IC chips, and there is a demand for reliable heat resistance in adhesion and connection portions of mounted circuits. One factor that reduces the adhesiveness and the reliability of connections is thermal stress caused by the difference in linear expansion coefficients between a semiconductor (die) and various types of materials adhered to the semiconductor (die). Specifically, the linear expansion coefficient of the semiconductor (die) is about 3 ppm/K, while the linear expansion coefficient of a mounting board has as high value, such as 15 ppm/K or more. Thus, thermal stress is generated by a manufacturing process step such as reflow and a heat cycle due to drive heat, so that adhesion and connection failures easily occur in the semiconductor (die).

Conventionally, solution-based die bonding pastes and sheet-like die attach films are being used as die bonding members for adhering a die to a die and for adhering a die to a substrate. There is a demand for these die bonding members to be highly heat resistant and thin, due to the increase in heat generation in highly integrated dies and the thinning of devices such as smartphones. On the other hand, it is known that the thickness of devices can be reduced by forming an adhesion part into a thin film, and a heat dissipation effect of the heated die can be obtained. As a method for forming a thin film of a die bonding member having a uniform thickness, there has been proposed a method of applying a curable resin composition as a die bonding member by inkjet printing (see PTL 1 and PTL 2).

### CITATION LIST

### Patent Literature

[PTL 1]
Japanese Unexamined Patent Application Publication No. 2018-065957
[PTL 2]
Japanese Unexamined Patent Application Publication No. 2014-237814

### SUMMARY OF INVENTION

### Technical Problem

An object of the present invention is to provide a curable composition for forming an adhesive structure that forms an adhesive structure excellent in adhesiveness, heat resistance, and flexibility.

### Solution to Problem

As a means for solving the above-described problems, a curable composition for forming an adhesive structure of the present embodiment is a curable composition for forming an adhesive structure that is discharged by an inkjet printing method, contains a glycidylamine-type epoxy compound, an oxetane compound, and a cationic polymerization initiator, and in which a proportion of the glycidylamine-type epoxy compound in the curable composition is 10% by mass or more.

### Advantageous Effects of Invention

According to the present embodiment, it is possible to provide a curable composition for forming an adhesive structure that forms an adhesive structure excellent in adhesiveness, heat resistance, and flexibility.

### BRIEF DESCRIPTION OF DRAWINGS

A more complete appreciation of embodiments of the present disclosure and many of the attendant advantages and features thereof can be readily obtained and understood from the following detailed description with reference to the accompanying drawings.

FIG. 1A is a schematic cross-sectional view in a film thickness direction, of an example of an adhesive structure of the present embodiment.

FIG. 1B is a schematic view of an example of the adhesive structure of the present embodiment viewed from above an adhesion layer.

FIG. 2A is a schematic cross-sectional view in the film thickness direction, of another example of an adhesive structure of the present embodiment.

FIG. 2B is a schematic view of another example of the adhesive structure of the present embodiment viewed from above the adhesion layer.

FIG. 3A is a schematic cross-sectional view in the film thickness direction, of another example of an adhesive structure of the present embodiment.

FIG. 3B is a schematic view of another example of the adhesive structure of the present embodiment viewed from above the adhesion layer.

FIG. 4 is a schematic cross-sectional view of an example of a semiconductor device of the present embodiment.

FIG. 5 is a schematic cross-sectional view of another example of the semiconductor device of the present embodiment.

FIG. 6A is a schematic cross-sectional view of another example of the semiconductor device of the present embodiment.

FIG. 6B is a schematic cross-sectional view of another example of the semiconductor device of the present embodiment.

FIG. 7A is a schematic cross-sectional view of another example of the semiconductor device of the present embodiment.

FIG. 7B is a schematic cross-sectional view of another example of the semiconductor device of the present embodiment.

FIG. 8A is a schematic cross-sectional view of another example of the semiconductor device of the present embodiment.

FIG. 8B is a schematic cross-sectional view of another example of the semiconductor device of the present embodiment.

FIG. 9 is a schematic cross-sectional view of another example of the semiconductor device of the present embodiment.

The accompanying drawings are intended to depict embodiments of the present disclosure and should not be interpreted to limit the scope thereof. The accompanying drawings are not to be considered as drawn to scale unless explicitly noted. Also, identical or similar reference numerals designate identical or similar components throughout the several views.

### DESCRIPTION OF EMBODIMENTS

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawings, embodiments of the present disclosure are described below. As used herein, the singular forms “a,” “an,” and “the” are intended to include the plural forms as well, unless the context clearly indicates otherwise.

### (Curable Composition for Forming Adhesive Structure)

A curable composition for forming an adhesive structure of the present embodiment is a curable composition for forming an adhesive structure that can be discharged by an inkjet printing method, and contains a glycidylamine-type epoxy compound, an oxetane compound, and a cationic polymerization initiator. The proportion of the glycidylamine-type epoxy compound in the curable composition is 10% by mass or more. The curable composition for forming an adhesive structure further contains another component, if desired.

In a technique of the related art (for example, PTL 1), there has been proposed a curable resin composition for use in an inkjet method, and the curable resin composition contains, in addition to an alicyclic epoxy monomer, an acrylonitrile copolymer (rubber) that imparts flexibility.

In such a curable resin composition of the related art, to reduce the viscosity of the curable resin composition, alicyclic epoxy monomers having low molecular weight are used. However, it is difficult to satisfy curing performance and properties of cured product with an alicyclic epoxy monomer having low molecular weight alone. Specifically, the curing reaction of the alicyclic epoxy monomer is fast and the glass transition temperature (Tg) of the cured product of the alicyclic epoxy monomer is high, and thus, the heat resistance is excellent. However, the elastic modulus of the cured product is high, so that the cured product has the disadvantage of being hard and brittle. In general, acrylonitrile copolymers (rubber) have high viscosity, and when a large amount of an acrylonitrile copolymer is added, the viscosity of the obtained product increases, so that the effect of imparting flexibility tends to be insufficient and further, there is a problem in that the ink materials and the blending ratios are limited.

On the other hand, non-alicyclic epoxy monomers (for example, glycidyl ether-type epoxy monomers) impart excellent flexibility to cured products, but have the disadvantages of a slow curing reaction and a low glass transition temperature (Tg). Thus, if a curable resin composition used as a die bonding member is a single material, there is a problem in that it is difficult to counteract an increase in heat generation of semiconductors and allow for a thinning of semiconductor packages.

In a technique of the related art (for example, PTL 1), it has been proposed to use an ink having a high viscosity at room temperature (25° C.) and heat the ink to a temperature of 50° C. or higher to reduce the viscosity, to adjust the viscosity to a viscosity suitable for an inkjet system.

However, when a heat-curable ink is heated to a high temperature, the ink liquid easily hardens and forms a gel, so that there is a problem in that it is not possible to use the ink over an extended time in an inkjet printing apparatus. Further, a hardening of the ink may result in clogging the fine nozzle holes of the inkjet system.

A curable composition for forming an adhesive structure of the present embodiment contains a glycidylamine-type epoxy compound, an oxetane compound, and a cationic polymerization initiator, and the proportion of the glycidylamine-type epoxy compound in the curable composition is 10% by mass or more. Thus, it is possible to impart an adhesive structure, which is a cured product of the curable composition for forming an adhesive structure, with adhesion characteristics including excellent heat resistance and flexibility. Further, the curable composition for forming an adhesive structure of the present embodiment does not easily evaporate when being heating, is stable even when the curable composition for forming an adhesive structure is heated, and the volume reduction of the cured product is low.

The curable composition for forming an adhesive structure according to embodiments of the present invention will be described below. The present invention is not limited to the embodiments described below, may be another embodiment, and may be subject to changes such as additions, modifications, and omissions within the scope conceivable for a person skilled in the art. All of these changed configurations are also included in the scope of the present invention, as long as an operation and an effect of the present invention are exhibited.

The curable composition for forming an adhesive structure contains a glycidylamine-type epoxy compound, an oxetane compound, and a cationic polymerization initiator. The proportion of the glycidylamine-type epoxy compound in the curable composition is 10% by mass or more. The curable composition for forming an adhesive structure further contains another component, if desired.

The viscosity of the curable composition for forming an adhesive structure is not particularly limited, as long as the curable composition for forming an adhesive structure can be discharged by an inkjet printing method. The viscosity can be appropriately selected according to a purpose, but is preferably 200 mPa·s or less, and more preferably 50 mPa·s or less at 25° C. If the viscosity of the curable composition for forming an adhesive structure at 25° C. is 200 mPa·s or less, it is possible to thin and evenly coat the adhesive structure by inkjet printing, without heating the curable composition for forming an adhesive structure to a high temperature. Further, if the viscosity of the curable composition for forming an adhesive structure at 25° C. is 200 mPa·s or less, the coating amount can be easily adjusted and the adhesive structure can be thinned, so that the filling performance is improved and it is possible to reduce the generation of bubbles and voids. Therefore, in particular, the filling performance in wire bonding and flip chip of semiconductors (dies) is improved, patterning coating can be performed in a desired pattern, and peeling of the adhesive structure can be suppressed.

A lower limit value of the viscosity of the curable composition for forming an adhesive structure is not particularly limited, as long as the curable composition for forming an adhesive structure can be discharged by an inkjet printing method.

The viscosity of the curable composition for forming an adhesive structure can be adjusted according to the structures and proportions of the glycidylamine-type epoxy compound and the oxetane compound, other added components, and the like.

The viscosity at 25° C. of the curable composition for forming an adhesive structure can be measured by a general method, such as the method described in JIS (Japanese Industrial Standard) Z8803, for example. As another example, a cone rotor (1° 34′×R24) in a cone-plate type rotational viscometer (for example, VISCOMETER TVE-22L, manufactured by Toki Sangyo Co., Ltd.) can be used to measure the viscosity at a number of revolutions of 10 rpm under circulating water having a constant temperature set to 25° C. To adjust the temperature of the circulating water, a constant temperature circulating temperature bath (for example, VISCOMATE VM-150III, manufactured by Toki Sangyo Co., Ltd.) can be used.

### <<Glycidylamine-Type Epoxy Compound>>

The glycidylamine-type epoxy compound (monomer) is not particularly limited, may be appropriately selected according to a purpose, and examples thereof include, but are not limited to, a compound represented by General Formula (1) below and a compound represented by General Formula (2) below. Each of these compounds may be used alone or in combination with others.

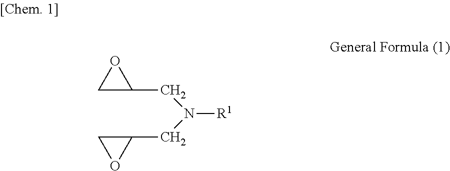

In General Formula (1) above, R¹ represents a monovalent aliphatic, aromatic, or alicyclic hydrocarbon group, or a group in which two or more groups selected from aliphatic, aromatic, and alicyclic hydrocarbon groups are bonded, or further, a group in which a glycidyl ether group is bonded to these hydrocarbon groups or to a group in which two or more of the hydrocarbon groups are bonded.

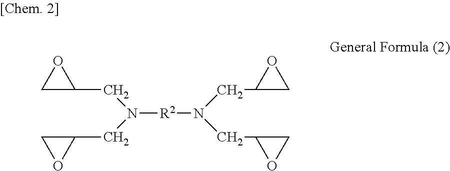

In General Formula (2) above, R² represents a monovalent aliphatic, aromatic, or alicyclic hydrocarbon group, or a group in which two or more groups selected from aliphatic, aromatic, and alicyclic hydrocarbon groups are bonded.

Specific examples of the glycidylamine-type epoxy compound include, but are not limited to, compounds represented by any one of Structural Formula 1 to Structural Formula 9 below. Each of these compounds may be used alone or in combination with others.

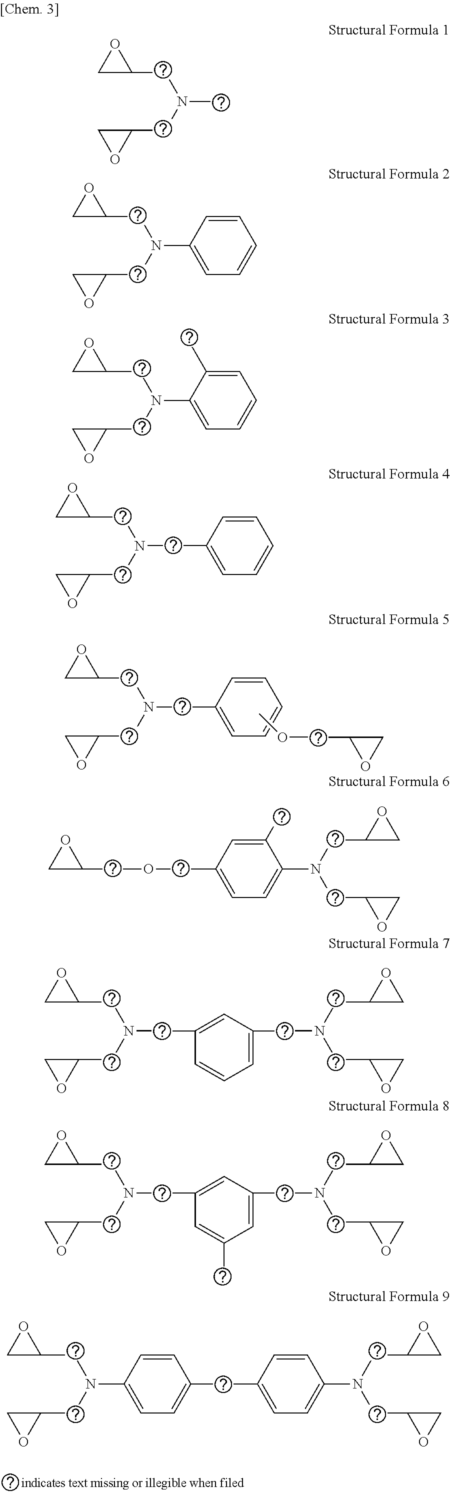

Among these compounds, the glycidylamine-type epoxy compound preferably contains at least any one trifunctional or higher functional glycidylamine-type epoxy compound selected from the group consisting of the compound represented by Structural Formula 5, the compound represented by Structural Formula 6, the compound represented by Structural Formula 7, the compound represented by Structural Formula 8, and the compound represented by Structural Formula 9, so that the adhesive structure, which is the cured product of the curable composition for forming an adhesive structure, has good adhesiveness and heat resistance.

The glycidylamine-type epoxy compound may be appropriately synthesized, or a commercially available product may be used as the glycidylamine-type epoxy compound. Examples of commercially available products of the glycidylamine-type epoxy compound include, but are not limited to, SUMI-EPOXY ELM-434, ELM-434VL, and ELM-100 (manufactured by Sumitomo Chemical Co., Ltd.), ADEKA RESIN EP-3950S, P-3950L, and EP-3980S (manufactured by ADEKA Corporation), YH-523, YH-513, and YH-404 (manufactured by Nippon Steel Chemical & Material Co., Ltd.), and TETRAD-X (Mitsubishi Gas Chemical Trading Inc.).

The proportion of the glycidylamine-type epoxy compound in the curable composition for forming an adhesive structure is 10% by mass or more, preferably 10% by mass or more and 40% by mass or less, and more preferably 15% by mass or more and 30% by mass or less, with respect to the total mass of the curable composition for forming an adhesive structure. When the proportion of the glycidylamine-type epoxy compound is less than 10% by mass, the heat resistance and the adhesiveness of the adhesive structure obtained from the curable composition for forming an adhesive structure decrease. On the other hand, when the proportion of the glycidylamine-type epoxy compound is 10% by mass or more, the adhesive structure, which is the cured product of the curable composition for forming an adhesive structure, has good heat resistance and adhesiveness. Further, the heat stability of a product obtained by mixing the curable composition for forming an adhesive structure with a cationic polymerization initiator is improved. When the proportion of the glycidylamine-type epoxy compound is 40% by mass or less, the viscosity of the curable composition for forming an adhesive structure can be easily set to a viscosity at which the curable composition for forming an adhesive structure can be discharged by an inkjet printing method.

### <<Oxetane Compound>>

The oxetane compound can adjust the viscosity of the curable composition for forming an adhesive structure, and in particular, can reduce the viscosity affected by the glycidylamine-type epoxy compound. The curing reaction by heat is fast, so that the components do not easily evaporate by heating, and bubbles (voids) are unlikely to form in the adhesive structure, which is the cured product of the curable composition for forming an adhesive structure. Further, flexibility can be imparted to the adhesive structure, which is the cured product of the curable composition for forming an adhesive structure. Specifically, polymerization occurs between at least one of the glycidylamine-type epoxy compound and the oxetane compound or between the oxetane compounds, and if a longer chain is formed, a higher flexibility can be imparted. If a conventional acrylonitrile copolymer (rubber), a (meth)acrylic monomer, or the like is used instead of the oxetane compound, the viscosity of the composition increases, and it is disadvantageously difficult to obtain a composition having a viscosity suitable for discharge by an inkjet printing method, and materials that may be used in the curing reaction by heat are limited. Therefore, the curable composition for forming an adhesive structure of the present embodiment has a viscosity at which the curable composition for forming an adhesive structure can be discharged by an inkjet printing method, and the curable composition for forming an adhesive structure contains the glycidylamine-type epoxy compound and the oxetane compound, so that monomers having low molecular weight are crosslinked by the curing reaction using heat.

The oxetane compound (monomer) is not particularly limited, as long as the viscosity of the curable composition for forming an adhesive structure can be set to a viscosity at which the curable composition for forming an adhesive structure can be discharged by an inkjet printing method. The oxetane compound may be appropriately selected according to a purpose and examples thereof include, but are not limited to, a compound represented by General Formula (3) below and a compound represented by General Formula (4) below. Each of these oxetane compounds may be used alone or in combination with others.

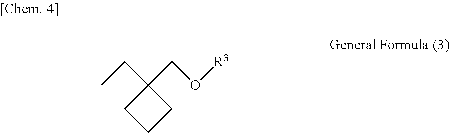

In General Formula (3) above, R³ represents a monovalent organic group.

Specific examples of the compound represented by General Formula (3) above include, but are not limited to, compounds represented by any one of Structural Formula 10 to Structural Formula 15 below.

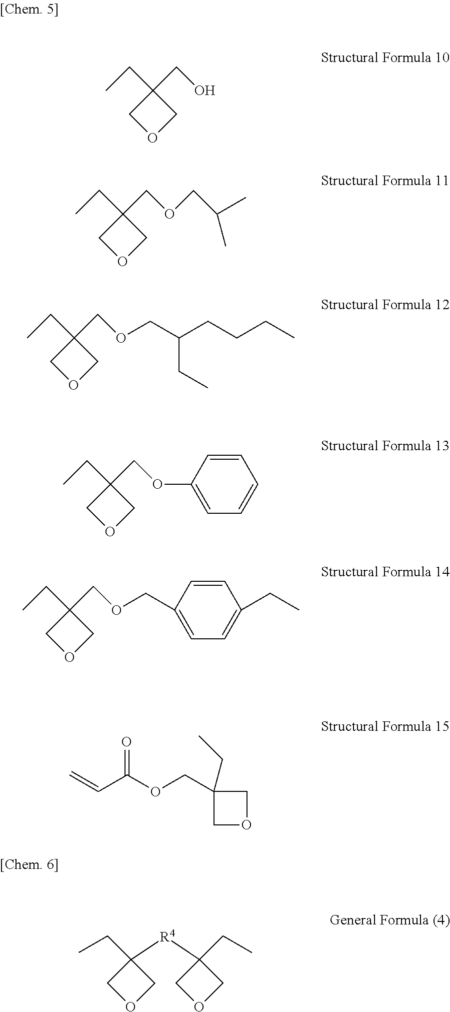

In General Formula (4) above, R⁴ represents a divalent hydrocarbon group, or a divalent organic group containing an ether group including R⁵—O—R⁶ or R⁵—O—R⁶—O—R⁷. R⁵, R⁶, and R⁷ each independently represent a hydrocarbon group. R⁵, R⁶, and R⁷ may be the same or may be different groups.

Specific examples of the compound represented by General Formula (4) above include, but are not limited to, compounds represented by any one of Structural Formula 16 to Structural Formula 18 below.

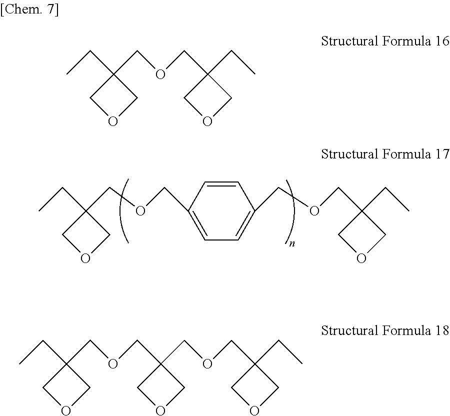

(in Structural Formula 17, n represents an integer of 1 or 2)

Among these, the oxetane compound preferably contains at least any one compound selected from the group consisting of the compound represented by Structural Formula 10, the compound represented by Structural Formula 12, the compound represented by Structural Formula 16, and the compound represented by Structural Formula 17, so that it is possible to obtain a viscosity at which the curable composition for forming an adhesive structure can be discharged by an inkjet printing method, and the adhesive structure, which is the cured product of the curable composition for forming an adhesive structure, has good adhesiveness and flexibility.

As for the oxetane compound, it is preferable that a cured product of the oxetane compound alone has a glass transition temperature (Tg) of 100° C. or less, from the viewpoint of the flexibility of the adhesive structure.

The glass transition temperature (Tg) of the cured product of the oxetane compound alone can be measured as follows. 1% by mass of SAN-AID SI-150 (manufactured by Sanshin Chemical Industry Co., Ltd.) are added as a thermal polymerization initiator to the oxetane compound, and the obtained solution is injected between two glass plates. Subsequently, the glass plates are heated at 100° C. for 2 hours, further heated at 200° C. for 1 hour, and then, a curing reaction by heat is conducted by heating the glass plates at 260° C. for 5 minutes. After that, a measurement sample is prepared by peeling the cured product from the two glass plates, and the glass transition temperature is measured by a rheometer (ARES-G2, manufactured by TA Instruments) under the following measurement conditions.

### [Measurement Conditions]

Measurement method: Torsion vibration
Measurement sample set: tension of 10 gf (Gap variable: initial value of about 10 mm)
Strain conditions: minimum torque of 0.3 g*cm (variable strain: initial value of 0.05%, maximum value of 1%)
Temperature: from 25° C. to 300° C., at 20° C./minute
Shape of sample: about 20 mm×5 mm (thickness: 100 μm)

From the viewpoint of imparting photocurability and heat curability, the oxetane compound preferably contains an oxetane acrylate having an oxetane acrylate group. When the oxetane compound contains an oxetane acrylate, good adhesive strength can be obtained when photocuring and heat curing are used in combination. The oxetane acrylate preferably contains the compound represented by Structural Formula 15 above.

The oxetane compound may be appropriately synthesized or a commercially available product may be used as the oxetane compound.

Examples of commercially available products of the oxetane compound include, but are not limited to, ARON OXETANE OXT-101, ARON OXETANE OXT-212, ARON OXETANE OXT-121, and ARON OXETANE OXT-221 (all manufactured by Toagosei Co., Ltd.), ETERNACOLL (registered trademark) HBOX, OXBP, and OXIPA (all manufactured by Ube Industries, Ltd.), OXE-10 ((3-ethyloxetan-3-yl)methyl acrylate), OXE-30 ((3-ethyloxetan-3-yl)methyl methacrylate), and MEDOL-10 ((3-ethyloxetan-3-yl)methyl acrylate) (all manufactured by Osaka Organic Chemical Industry Co., Ltd.).

The proportion of the oxetane compound in the curable composition for forming an adhesive structure is not particularly limited, as long as the curable composition for forming an adhesive structure has a viscosity at which the curable composition for forming an adhesive structure can be discharged by an inkjet printing method. The proportion of the oxetane compound can be appropriately selected according to the type of the glycidylamine-type epoxy compound and the like. However, the proportion of the oxetane compound is preferably 10% by mass or more and 60% by mass or less, and more preferably 20% by mass or more and 40% by mass or less. When the proportion of the oxetane compound is 10% by mass or more, the adhesive structure obtained from the curable composition for forming an adhesive structure has good flexibility, and further, the viscosity of the curable composition for forming an adhesive structure can be set to a viscosity that is suitable for discharge by an inkjet printing method. When the proportion of the oxetane compound is 60% by mass or less, the adhesive structure obtained from the curable composition for forming an adhesive structure has good heat resistance and adhesiveness.

The proportion of the oxetane compound corresponds to a proportion relative to the total mass of the curable composition for forming an adhesive structure when the curable composition for forming an adhesive structure contains another component mentioned above.

### <<Cationic Polymerization Initiator>>

The cationic polymerization initiator includes a thermal cationic polymerization initiator and a photo-cationic polymerization initiator.

If an adhesive structure formed of an epoxy resin is to be obtained, the curable composition for forming an adhesive structure contains a thermal cationic polymerization initiator, and the curable composition for forming an adhesive structure formed between two substrates, which are adhesion targets, can be adhered by heat curing. Further, if a material of the substrate is light-transmissive, the cationic polymerization initiator may contain the photo-cationic polymerization initiator, so that the curable composition for forming an adhesive structure can be irradiated with light to be photocured. Moreover, the cationic polymerization initiator may contain the thermal cationic polymerization initiator and the photo-cationic polymerization initiator, so that an adhesion method by curing using both heat and light can be employed.

### —Thermal Cationic Polymerization Initiator—

The thermal cationic polymerization initiator is not particularly limited and may be appropriately selected according to a purpose. Examples of the thermal cationic polymerization initiator include, but are not limited to, a photoacid generator such as an onium salt having a sulfonium ion or an iodonium ion as a cationic part. Among these thermal cationic polymerization initiators, it is preferable that a cationic part of the thermal cationic polymerization initiator is a sulfonium ion. Further, it is preferable that the thermal cationic polymerization initiator is a compound including an anionic part that is less corrosive to metal parts.

Specific examples of the anionic part (generated acid) include, but are not limited to, compounds such as B(C₆F₅)₄ and PF₃(C₂F₅)₃.

The thermal cationic polymerization initiator may be appropriately synthesized or a commercially available product may be used as the thermal cationic polymerization initiator. Examples of commercially available products of the thermal cationic polymerization initiator include, but are not limited to, SAN-AID SI-60, SAN-AID SI-80, SAN-AID SI-100, SAN-AID SI-110, and SAN-AID SI-150 (all manufactured by Sanshin Chemical Industry Co., Ltd.), TA-100, TA-100FG, IK-1, and IK-1FG (manufactured by San-Apro Ltd.), OMNICAT 250 (former IRGACURE 250), and OMNICAT 270 (former IRGACURE 270) (both manufactured by IGM Resins B.V.).

The proportion of the thermal cationic polymerization initiator in the curable composition for forming an adhesive structure is not particularly limited and can be appropriately selected according to a purpose. However, the proportion of the thermal cationic polymerization initiator is preferably 0.1% by mass or more and 10% by mass or less, and more preferably 1% by mass or more and 10% by mass or less, with respect to the total mass of the curable composition for forming an adhesive structure. If the proportion of the thermal cationic polymerization initiator is 0.1% by mass or more and 10% by mass or less, the curing reaction can be appropriately completed, and unreacted components are less likely to remain as reactive impurities.

### —Photo-Cationic Polymerization Initiator—

The photo-cationic polymerization initiator is not particularly limited and may be appropriately selected according to a purpose. Examples of the photo-cationic polymerization initiator include, but are not limited to, a photoacid generator such as an onium salt having a sulfonium ion or an iodonium ion as a cationic part. Each of these photo-cationic polymerization initiators may be used alone or in combination with others. Among these photo-cationic polymerization initiators, a compound having an anionic part that is less corrosive to metal parts is preferable.

Specific examples of the photo-cationic polymerization initiator include, but are not limited to, compounds containing B(C₆F₅)₄ or PF₃(C₂F₅)₃ as an anionic part (generated acid).

The photo-cationic polymerization initiator may be appropriately synthesized, or a commercially available product may be used as the photo-cationic polymerization initiator. Examples of commercially available products of the photo-cationic polymerization initiator include, but are not limited to, CPI (registered trademark)-110P, CPI (registered trademark)-110A, CPI (registered trademark)-210S, CPI (registered trademark)-110B, CPI (registered trademark)-310B, CPI (registered trademark)-410B, CPI (registered trademark)-310FG, and IK-1FG (manufactured by San-Apro Ltd.).

The proportion of the cationic polymerization initiator can be confirmed by the proportion of a reaction residue (for example, sulfide) contained in the adhesive structure. The composition of materials in the adhesive structure can be analyzed by pyrolysis gas chromatography-mass spectrometry (GC/MS) and real-time mass spectrometry (DART-MS).

### <<Other Components>>

The curable composition for forming an adhesive structure may contain other components excluding the glycidylamine-type epoxy compound and the oxetane compound, as long as the effect of the present invention is not impaired.

The glycidylamine-type epoxy compound and the oxetane compound have low molecular weights, and thus, have low viscosity at room temperature (about 25° C.), so that the selectable range of other materials to be added and the blending ratios are improved. This facilitates the optimization of the curable composition for forming an adhesive structure in accordance with an application.

The other components are not particularly limited and may be appropriately selected according to a purpose. Examples thereof include, but are not limited to, monomers other than the glycidylamine-type epoxy compound and the oxetane compound, silicone compounds, inorganic particles, resins and/or resin particles, adhesion improvers, and polymerization initiators other than the cationic polymerization initiator. Each of these components may be used alone or in combination with others.

### —Monomer Other Than Glycidylamine-Type Epoxy Compound and Oxetane Compound—

If the curable composition for forming an adhesive structure contains a monomer other than the glycidylamine-type epoxy compound and the oxetane compound, it is possible to improve the compatibility with the glycidylamine-type epoxy compound and the oxetane compound. Further, the viscosity of the curable composition for forming an adhesive structure can be easily adjusted to a more appropriate viscosity, so that it is easy to adjust the film elasticity of the adhesive structure that is the cured product of the curable composition for forming an adhesive structure and further, it is possible to improve the adhesiveness. Moreover, it is also possible to impart a photocuring function.

The monomer other than the glycidylamine-type epoxy compound and the oxetane compound is not particularly limited and can be appropriately selected according to a purpose. Examples thereof include, but are not limited to, alicyclic epoxy compounds, glycidyl ether-type epoxy compounds, (meth)acrylate monomers, and urethane monomers. Each of these monomers may be used alone or in combination with others. Among these monomers, the curable composition for forming an adhesive structure preferably contains the alicyclic epoxy compound or the glycidyl ether-type epoxy compound, from the viewpoint of adjusting the viscosity of the curable composition for forming an adhesive structure, and the adhesive strength of the adhesive structure, which is the cured product of the curable composition for forming an adhesive structure.

The proportion of the monomer other than the glycidylamine-type epoxy compound and the oxetane compound in the curable composition is not particularly limited, as long as the effect of the present invention is not impaired, and the proportion may be appropriately selected according to a purpose. However, the proportion is preferably 1% by mass or more and 60% by mass or less, more preferably 5% by mass or more and 50% by mass or less, and even more preferably 5% by mass or more and 30% by mass or less, with respect to the total mass of the curable composition for forming an adhesive structure. The proportion of the monomer other than the glycidylamine-type epoxy compound and the oxetane compound is preferably 1% by mass or more and 60% by mass or less, because in this case, the compatibility with the glycidylamine-type epoxy compound and the oxetane compound is excellent, and the viscosity can be lowered. The proportion of the monomer other than the glycidylamine-type epoxy compound and the oxetane compound is preferably 5% by mass or more and 30% by mass or less, because in this case, the adhesive structure, which is the cured product, can be obtained without impairing the characteristics of the cured products of the glycidylamine-type epoxy compound and the oxetane compound, which are the main components.

### —Alicyclic Epoxy Compound—

The curing reaction of the alicyclic epoxy compound is fast, so that it is possible to improve the manufacturing efficiency of the adhesive structure. Further, the glass transition temperature (Tg) of the cured product of the alicyclic epoxy compound is high, so that heat resistance can be imparted to the adhesive structure, which is the cured product of the curable composition for forming an adhesive structure.

The alicyclic epoxy compound (monomer) is not particularly limited, as long as the curable composition for forming an adhesive structure has a viscosity at which the curable composition for forming an adhesive structure can be discharged by an inkjet printing method. The alicyclic epoxy compound may be appropriately selected according to a purpose and examples thereof include, but are not limited to, a compound represented by General Formula (5) below and a compound represented by General Formula (6) below. Each of these compounds may be used alone or in combination with others.

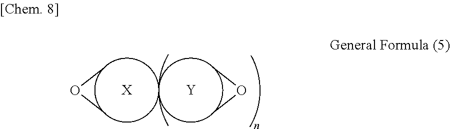

In General Formula (5) above, X and Y each independently represent a hydrocarbon containing one or more non-aromatic saturated or unsaturated carbocyclic rings, and n represents an integer of 0 to 3. Zero, one, or two monovalent organic groups are bonded to the carbons of the carbocyclic rings of X and Y. X and Y may be the same or may be different from each other.

Among these compounds, the compound represented by General Formula (5) above is preferably a compound represented by General Formula (5a) below.

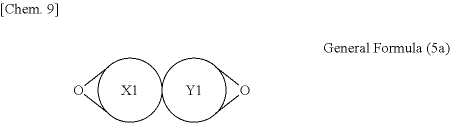

In General Formula (5a) above, X1 and Y1 each independently represent a 5-membered or 6-membered saturated carbocyclic ring. Zero, one, or two monovalent organic groups are bonded to the carbons of the carbocyclic rings of X1 and Y1. X1 and Y1 may be the same or may be different from each other.

Specific examples of the compound represented by General Formula (5) above include, but are not limited to, compounds represented by any one of Structural Formula 19 to Structural Formula 26 below.

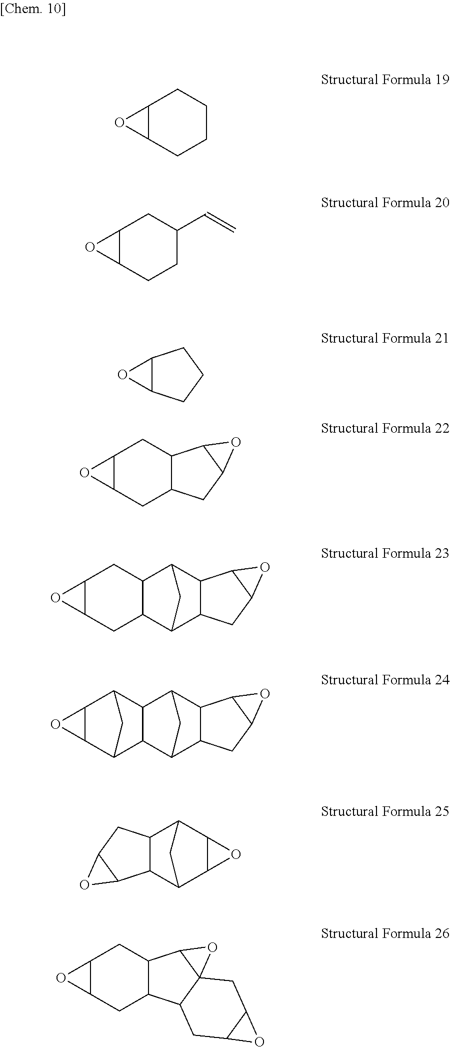

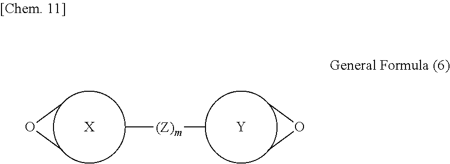

In General Formula (6) above, X and Y each independently represent a hydrocarbon containing one or more non-aromatic saturated or unsaturated carbocyclic rings, Z represents an alicyclic hydrocarbon or a monofunctional alicyclic epoxy, and m represents an integer of 0 or 1. Zero, one, or two monovalent organic groups are bonded to the carbons of the carbocyclic rings of X and Y. X and Y may be the same or may be different from each other.

Among these, the compound represented by General Formula (6) above is preferably a compound represented by General Formula (6a) below.

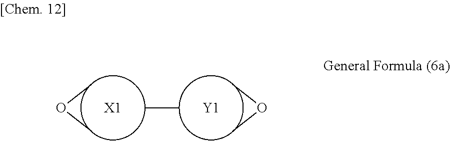

In General Formula (6a) above, X1 and Y1 each independently represent a 5-membered or 6-membered saturated carbocyclic ring. Zero, one, or two monovalent organic groups are bonded to the carbons of the carbocyclic rings of X1 and Y1. X1 and Y1 may be the same or may be different from each other.

Specific examples of the compound represented by General Formula (6) above and the compound represented by General Formula (6a) above include, but are not limited to, compounds represented by any one of Structural Formula 27 to Structural Formula 32 below.

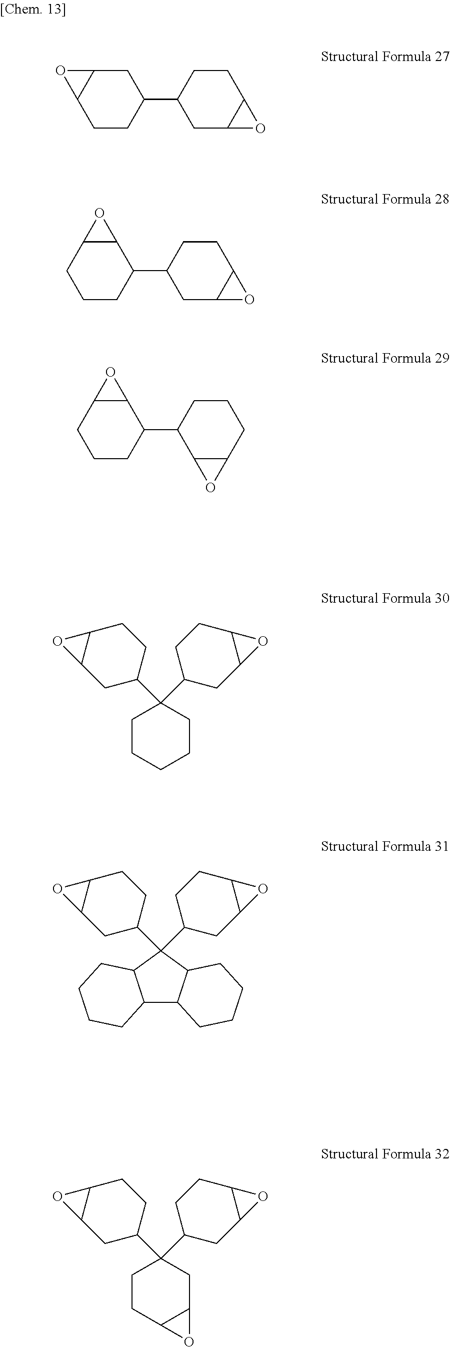

Further, examples of the alicyclic epoxy compound include, but are not limited to, a compound represented by Structural Formula 33 below, a compound represented by Structural Formula 34 below, and a compound represented by Structural Formula 35 below.

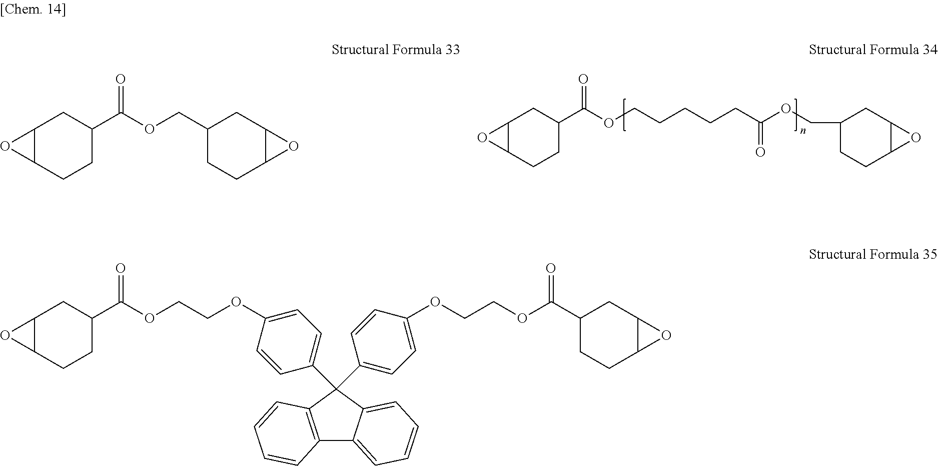

(in Structural Formula 34 above, n represents an integer of 1 or 2)

Among these, the alicyclic epoxy compound preferably contains at least any one compound selected from the group consisting of the compound represented by Structural Formula 20, the compound represented by Structural Formula 22, the compound represented by Structural Formula 27, the compound represented by Structural Formula 28, and the compound represented by Structural Formula 29, so that it is possible to obtain a viscosity at which the curable composition can be discharged by an inkjet printing method, and so that the adhesive structure has good adhesiveness and heat resistance.

The alicyclic epoxy compound may be appropriately synthesized or a commercially available product may be used as the alicyclic epoxy compound.

Examples of commercially available products of the alicyclic epoxy compound include, but are not limited to, EPOCHALIC THI-DE, EPOCHALIC DE-102, EPOCHALIC DE-103, and VNBB-ME (all manufactured by ENEOS Corporation), DCPD-DE (manufactured by Japan Material Technologies Corporation), CELLOXIDE (CEL) 8010P, CEL2010P, CEL2081, and CEL2000 (all manufactured by Daicel Corporation).

### —Glycidyl Ether-Type Epoxy Compound—

The glycidyl ether-type epoxy compound (monomer) is not particularly limited and may be appropriately selected according to a purpose. Examples of the glycidyl ether-type epoxy compound include, but are not limited to, allyl diglycidyl ether and bisphenol-type diglycidyl ether. Each of these glycidyl ether-type epoxy compounds may be used alone or in combination with others.

Specific examples of the glycidyl ether-type epoxy compound include, but are not limited to, compounds represented by any one of Structural Formula 36 to Structural Formula 43 below. Each of these compounds may be used alone or in combination with others.

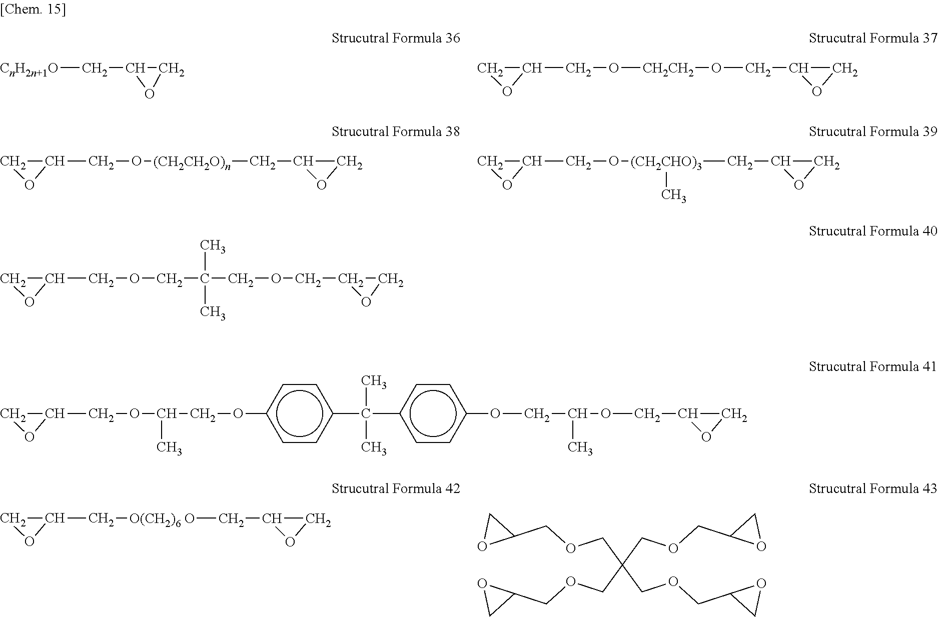

(in Structural Formula 36 above, n represents 12, and in Structural Formula 38, n represents 9)

The glycidyl ether-type epoxy compound may be appropriately synthesized or a commercially available product may be used as the glycidyl ether-type epoxy compound.

Examples of commercially available products of the glycidyl ether-type epoxy compound include, but are not limited to, RIKARESIN DME-100 (manufactured by New Japan Chemical Co., Ltd.), EPOLIGHT M-1230, EPOLIGHT 40E, EPOLIGHT 100E, EPOLIGHT 200E, EPOLIGHT 400E, EPOLIGHT 70P, EPOLIGHT 200P, EPOLIGHT 400P, EPOLIGHT 1500NP, EPOLIGHT 1600, EPOLIGHT 80MF, and EPOLIGHT 100MF (all manufactured by Kyoeisha Chemical Co., Ltd.), SHOFREE (registered trademark) PETG, SHOFREE (registered trademark) BATG (all manufactured by Showa Denko K.K.), DENACOL EX-614B, DENACOL EX-313, DENACOL EX-512, DENACOL EX-321, DENACOL EX-321L, DENACOL EX-612, DENACOL EX-614, DENACOL EX-622, DENACOL EX-314, DENACOL EX-421, DENACOL EX-521, DENACOL EX-411, DENACOL EX-171, DENACOL EX-146, DENACOL EX-121, DENACOL EX-141, DENACOL EX-145, DENACOL EX-147, DENACOL EX-192, DENACOL EX-731, and DENACOL EX-991L (all manufactured by Nagase ChemteX Corporation), YL9028 (manufactured by Mitsubishi Chemical Corporation), and EPOGOSEY (registered trademark) OCR-EP, EPOGOSEY (registered trademark) NPG (D), DY-BP, and EPOGOSEY (registered trademark) HD (D) (all manufactured by Yokkaichi Chemical Co., Ltd.).

### —(Meth)acrylate Monomer—

The (meth)acrylate monomer is not particularly limited and may be appropriately selected from general photopolymerization-type or thermal polymerization-type (meth)acrylate monomers according to a purpose. Each of these monomers may be used alone or in combination with others. In the present disclosure, “(meth)acrylate monomer” refers to “acrylate and methacrylate monomers”.

The (meth)acrylate monomer may be appropriately synthesized or a commercially available product may be used as the (meth)acrylate monomer.

Examples of commercially available products of the (meth)acrylate monomer include, but are not limited to, AOMA (registered trademark) (manufactured by Nippon Shokubai Co., Ltd.), HEA (hydroxyethyl acrylate), HPA (hydroxypropyl acrylate), 4-HBA (4-hydroxybutyl acrylate), AIB (isobutyl acrylate), TBA (t-butyl acrylate), NOAA (n-octyl acrylate), INAA (isononyl acrylate), VISCOAT #197 (nonyl acrylate), IDAA (nonyl acrylate), LA (lauryl acrylate), STA (stearyl acrylate), ISTA (isostearyl acrylate), IBXA (isobornyl acrylate), VISCOAT #155 (cyclohexyl acrylate), VISCOAT #196 (3,3,5-trimethylcyclohexyl acrylate), VISCOAT #160 (benzyl acrylate), VISCOAT #192 (phenoxyethyl acrylate), VISCOAT #150 (tetrahydrofurfuryl acrylate), VISCOAT #190 (ethyl carbitol acrylate), 2-MTA (methoxyethyl acrylate), VISCOAT #MTG (methoxytriethylene glycol acrylate), bismer MPE400A (methoxy polyethylene glycol acrylate), bismer MPE550A (methoxy polyethylene glycol acrylate), VISCOAT #200 (cyclic trimethylolpropane formal acrylate) (all manufactured by Osaka Organic Chemical Industry Ltd.), A-LEN-10 (ethoxylated-o-phenylphenol acrylate), AM-90G (ethoxylated-o-phenylphenol acrylate), AM-130G (ethoxylated-o-phenylphenol acrylate), AMP-20GY (ethoxylated-o-phenylphenol acrylate), A-SA (2-acryloyloxyethyl succinic acid), 701A (2-hydroxy-3-methacrylpropyl acrylate), A-200 (polyethylene glycol #200 diacrylate), A-400 (polyethylene glycol #400 diacrylate), A-600 (polyethylene glycol #600 diacrylate), A-100 (polyethylene glycol #100 diacrylate), ABE-300 (ethoxylated bisphenol A diacrylate), A-BPE-10 (ethoxylated bisphenol A diacrylate), A-BPE-20 (ethoxylated bisphenol A diacrylate), A-BPE-4 (ethoxylated bisphenol A diacrylate), A-DCP (tricyclodecane dimethanol diacrylate), A-DOD-N (1,10-decane diol diacrylate), A-HD-N (1,6-hexanediol diacrylate), A-NOD-N (1,6-hexanediol diacrylate), APG-200 (tripropylene glycol diacrylate), APG-400 (polypropylene glycol #400 diacrylate), APG-700 (polypropylene glycol #700 diacrylate), A-PTMG-65 (polytetramethylene glycol #650 diacrylate), A-9300 (polytetramethylene glycol #650 diacrylate), A-GLY-9E (ethoxylated glycerol triacrylate), A-GLY-20E (ethoxylated glycerol triacrylate), A-TMM-3 (pentaerythritol tri- or tetra-acrylate), A-TMM-3L (pentaerythritol tri- or tetra-acrylate), A-TMPT (trimethylolpropane triacrylate), AD-TMP (ditrimethylolpropane tetraacrylate), ATM-35E (ethoxylated pentaerythritol tetraacrylate), A-TMMT (pentaerythritol tetraacrylate), A-9550 (dipentaerythritol polyacrylate), A-DPH (pentafunctional or hexafunctional (alkoxylated) dipentaerythritol polyacrylate) (all manufactured by Shin-Nakamura Chemical Co., Ltd.), SR440 (isooctyl acrylate), SR849D (tridecyl acrylate), and SR395 (isodecyl acrylate) (all manufactured by Tomoe Engineering Co., Ltd.).

### —Urethane Monomer—

The urethane monomer is not particularly limited and may be appropriately selected from general urethane monomers according to a purpose. Examples of the urethane monomer include, but are not limited to, urethane acrylate monomers. Each of these urethane monomers may be used alone or in combination with others.

The urethane monomer may be appropriately synthesized or a commercially available product may be used as the urethane monomer.

Examples of commercially available products of the urethane monomer include, but are not limited to, UF-3003, UF-3003M, UF-3007, UF-3007M, and UF-3123M (all manufactured by Kyoeisha Chemical Co., Ltd.).

### —Silicone Compound—

The silicone compound is not particularly limited and may be appropriately selected from general silicone compounds according to a purpose. Examples of the silicone compound include, but are not limited to, a silicone compound having a reactive group at one end or both ends of polydimethylsiloxane. Each of these silicone compounds may be used alone or in combination with others.

The silicone compound may be appropriately synthesized or a commercially available product may be used as the silicone compound.

Examples of commercially available products of the silicone compound include, but are not limited to, SILAPLANE (registered trademark) FM-3311, FM-3321, FM-3325 (all manufactured by JNC Corporation), STP-103-UV, and STP-104-UV (both manufactured by Shin-Etsu Chemical Co., Ltd.).

The proportion of the silicone compound in the curable composition is not particularly limited, as long as the effect of the present invention is not impaired, and the proportion may be appropriately selected according to a purpose. However, the proportion of the silicone compound is preferably 1% by mass or more and 50% by mass or less, more preferably 5% by mass or more and 50% by mass or less, and even more preferably 5% by mass or more and 30% by mass or less, with respect to the total mass of the curable composition for forming an adhesive structure. The proportion of the silicone compound is preferably 1% by mass or more and 50% by mass or less, because in this case, the compatibility with the glycidylamine-type epoxy compound and the oxetane compound is excellent, and the viscosity can be lowered. The proportion of the silicone compound is more preferably 5% by mass or more and 30% by mass or less, because in this case, the adhesive structure, which is the cured product, can be obtained without impairing the characteristics of the cured products of the glycidylamine-type epoxy compound and the oxetane compound, which are the main components.

### —Inorganic Particles—

When the curable composition for forming an adhesive structure contains the inorganic particles, the linear expansion coefficient of the adhesive structure is further reduced, and it is possible to further improve the strength of the adhesive structure, which is the cured product of the curable composition for forming an adhesive structure.

The inorganic particles are not particularly limited and may be appropriately selected from known inorganic particles. Examples of the inorganic particles include, but are not limited to, ceramic materials, metal materials, and magnetic particles. Each of these types of inorganic particles may be used alone or in combination with others.

Examples of the ceramic material include, but are not limited to, silica (SiO₂), aluminum oxide (Al₂O₃), aluminum nitride (AlN), and boron nitride (BN). The ceramic material has a smaller linear expansion coefficient and a higher glass transition temperature than the resin material, so that it is possible to reduce the linear expansion coefficient of the adhesive structure and improve the film strength at high temperature. Therefore, it is possible to impart a function of suppressing thermal expansion when the adhesive structure is heated at a high temperature.

Examples of the metal material include, but are not limited to, metals such as Au, Ag, Pd, Cu, Ni, Pt, Fe, and Co; and solder materials such as Sn/Pb and Sn/Ag/Cu. The metal material particles can impart conductivity to the adhesive structure.

Examples of the magnetic particles include, but are not limited to, iron (Fe), nickel (Ni), and cobalt (Co). The magnetic particles can impart a function of shielding electromagnetic waves.

The inorganic particles may be appropriately synthesized or a commercially available product may be used for the inorganic particles.

Examples of commercially available products for the inorganic particles include, but are not limited to, AEROSIL (registered trademark) OX50, AEROSIL (registered trademark) 50, AEROSIL (registered trademark) 90G, AEROSIL (registered trademark) 130, AEROSIL (registered trademark) 150, AEROSIL (registered trademark) 200, AEROSIL (registered trademark) 300, AEROSIL (registered trademark) 380, AEROSIL (registered trademark) RM50, AEROSIL (registered trademark) R711, AEROSIL (registered trademark) R7200, AEROXIDE (registered trademark) P25, AEROXIDE (registered trademark) P90 AluC (all manufactured by Nippon Aerosil Co., Ltd.), SEAHOSTAR (registered trademark) KE-S10, SEAHOSTAR (registered trademark) KE-S30, and SEAHOSTAR (registered trademark) KE-S50 (all manufactured by Nippon Shokubai Co., Ltd.).

The primary average particle diameter (D50) of the inorganic particles is not particularly limited and may be appropriately selected according to a purpose, but is preferably 0.1 μm or more and 5 μm or less, and more preferably 0.1 μm or more and 1 μm or less. When the primary average particle diameter (D50) of the inorganic particles is 0.1 μm or more, it is possible to suppress an increase in the viscosity of the curable composition for forming an adhesive structure. When the primary average particle diameter (D50) of the inorganic particles is 5 μm or less, the fine nozzle holes are less likely to be clogged when the curable composition for forming an adhesive structure is discharged by an inkjet printing method. The primary average particle diameter (D50) of the inorganic particles can be measured by a dynamic image analysis method, a dynamic light scattering method (DLS), and the like.

The proportion of the inorganic particles in the curable composition for forming an adhesive structure is not particularly limited and can be appropriately selected according to a purpose. However, the proportion of the inorganic particles is preferably 5% by mass or more and 70% by mass or less, and more preferably 5% by mass or more and 50% by mass or less, with respect to the total mass of the curable composition for forming an adhesive structure. When the proportion of the inorganic particles is 5% by mass or more, the effects of linear thermal expansion and film strength are easily obtained. When the proportion of the inorganic particles is 70% by mass or less, the adhesive structure is unlikely to be brittle, and further, it is possible to suppress an increase in the viscosity of the curable composition for forming an adhesive structure, so that the curable composition for forming an adhesive structure can be suitably used in an inkjet printing method.

—Resin and/or Resin Particles—

When the curable composition for forming an adhesive structure contains the resin and/or the resin particles, the flexibility, the heat resistance, and the adhesiveness of the adhesive structure, which is the cured product of the curable composition for forming an adhesive structure, can be further improved, and it is possible to further relax thermal stress. Further, the viscosity of the curable composition for forming an adhesive structure can be easily adjusted to a more appropriate viscosity, so that it is easy to adjust the elasticity of the adhesive structure that is the cured product of the curable composition for forming an adhesive structure.

The resin and/or the resin particles are not particularly limited and may be appropriately selected according to a purpose, as long as the effect of the present embodiment is not impaired. However, the glass transition temperature (Tg) of the resin and/or the resin particles is preferably low to relieve thermal stress, and more preferably, the glass transition temperature (Tg) is about 30° C. or less, which is about the same as room temperature. The glass transition temperature (Tg) of the resin and/or the resin particles can be measured by a thermal analysis method (such as TG-DTA and DSC).

It is preferable to use, as the resin and/or the resin particles, a material including a straight chain polymer having at least one characteristic among low elasticity and flexibility. Examples of the resin and/or the resin particles include, but are not limited to, styrene-butadiene-based resins, acrylonitrile-butadiene resins, (meth)acrylic resins, epoxy-based resins other than resins formed by the polyfunctional alicyclic epoxy compounds, urethane-based resins, phenol-based resins, polyimide-based resins, ester-based resins, vinyl-based resins, silicone-based resins, styrene-based resins, cellulose-based resins, amide-based resins, (meth)acrylic resins, melamine resins, fluorine-based resins, and mixtures of a plurality of types of these resins. Each of these resins may be used alone or in combination with others. Further, polymer particles having a core-shell type multilayered structure in which a rubber-like polymer is arranged inside an acrylic copolymer portion may be used. Among these resins and/or resin particles, styrene-butadiene-based resins, (meth)acrylic resins, epoxy resins other than resins formed by the alicyclic epoxy compounds, silicone-based resins, and polyimide-based resins are preferably, because these resins have good heat resistance.

Here, the resin and/or the resin particles having “low elasticity” refers to a material having an elastic modulus of 500 MPa or less.

The elastic modulus of the resin and/or the resin particles can be determined, for example, by measuring the indentation elastic modulus with a microhardness tester (for example, FISCHERSCOPE (registered trademark) HM2000, manufactured by Fischer Instruments Co., Ltd.).

The resin and/or the resin particles having “flexibility” refers to a material having an elastic deformation power of 70% or more.

The elastic deformation power of the resin and/or the resin particles can be determined, for example, by measuring the indentation elastic modulus with a microhardness tester (for example, FISCHERSCOPE (registered trademark) HM2000, manufactured by Fischer Instruments Co., Ltd.).

The resin and/or the resin particles may be appropriately synthesized or a commercially available product may be used as the resin and/or the resin particles.

Examples of commercially available products of the resin include, but are not limited to, ARUFON (registered trademark) US-1000, ARUFON (registered trademark) UH-2000, ARUFON (registered trademark) UC-3000, ARUFON (registered trademark) UG-4000, ARUFON (registered trademark) UF-5000, and ARUFON (registered trademark) US-600.

Examples of commercially available products of the resin particles include, but are not limited to, KANE ACE (registered trademark) MX-150, KANE ACE (registered trademark) MX-553 (both manufactured by Kaneka Corporation), FINE SPHERE (registered trademark) MG-155, FINE SPHERE (registered trademark) MG-351, FINE SPHERE (registered trademark) MG-451, FINE SPHERE (registered trademark) MG-651, FINE SPHERE (registered trademark) PZP-1003, FINE SPHERE (registered trademark) BGK-001 (all manufactured by Nippon Paint Industrial Coatings Co., Ltd.), METABLEN (registered trademark) C-223A, METABLEN (registered trademark) C-215AC-201A, METABLEN (registered trademark) C-140A, METABLEN (registered trademark) E-860A, METABLEN (registered trademark) E-870A, METABLEN (registered trademark) E-875A, METABLEN (registered trademark) W-300A, METABLEN (registered trademark) W-450A, METABLEN (registered trademark) W-600A, METABLEN (registered trademark)) W-377, METABLEN (registered trademark) S-2002, METABLEN (registered trademark) S-2006, METABLEN (registered trademark) S-2501, METABLEN (registered trademark) S-2030, METABLEN (registered trademark) S-2100, METABLEN (registered trademark) S-2200, METABLEN (registered trademark) SRK200A, METABLEN (registered trademark) SX-006, METABLEN (registered trademark) SX-00 (all manufactured by Mitsubishi Chemical Corporation), ZEFIAC F351, STAPHYLOID AC-3355, AC-3816N, AC-3832SD, AC-4030, and AC-3388 (all manufactured by Aica Kogyo Company, Limited).

The primary average particle diameter (D50) of the resin particles is not particularly limited and may be appropriately selected according to a purpose, but is preferably 0.1 μm or more and 5 μm or less, and more preferably 0.1 μm or more and 1 μm or less. When the primary average particle diameter (D50) of the resin particles is 0.1 μm or more, it is possible to suppress an increase in the viscosity of the curable composition for forming an adhesive structure. When the primary average particle diameter (D50) of the resin particles is 5 μm or less, the fine nozzle holes are less likely to be clogged when the curable composition for forming an adhesive structure is discharged by an inkjet printing method.

The primary average particle diameter (D50) of the resin particles can be measured by a dynamic image analysis method, a dynamic light scattering method (DLS), and the like.

The proportion of the resin particles in the curable composition for forming an adhesive structure is not particularly limited and can be appropriately selected according to a purpose. However, the proportion of the resin particles is preferably 1% by mass or more and 50% by mass or less, more preferably 5% by mass or more and 50% by mass or less, and even more preferably 3% by mass or more and 20% by mass or less, with respect to the total mass of the curable composition for forming an adhesive structure. When the proportion of the resin particles is 1% by mass or more, the thermal stress can be relaxed more suitably. When the proportion of the resin particles is 50% by mass or less, it is possible to suppress an increase in the viscosity of the curable composition for forming an adhesive structure, so that the curable composition for forming an adhesive structure can be suitably used in an inkjet printing method and further, it is less likely that bubbles or voids are generated at high temperatures.

### —Adhesion Improver—

When the curable composition for forming an adhesive structure contains the adhesion improver, it is possible to improve the adhesiveness of the adhesive structure.

The adhesion improver is not particularly limited and may be appropriately selected according to a purpose. However, the adhesion improver contains an organic substance and silicon, and a silane coupling agent having two or more different reactive groups in the molecule is particularly preferable to improve the adhesiveness to an adhesion target (in particular, a semiconductor and a substrate).

The adhesion improver may be appropriately synthesized or a commercially available product may be used as the adhesion improver.

Examples of commercially available products used as the adhesion improver include, but are not limited to, DOWSIL Z-6040, DOWSIL Z-6062 (both manufactured by DOW), and KBM-403 (manufactured by Shin-Etsu Chemical Co., Ltd.).

The proportion of the adhesion improver in the curable composition for forming an adhesive structure is not particularly limited and can be appropriately selected according to a purpose. However, the proportion of the adhesion improver is preferably 0.1% by mass or more and 20% by mass or less, and more preferably 0.1% by mass or more and 5% by mass or less, with respect to the total mass of the curable composition for forming an adhesive structure. When the proportion of the adhesion improver is 0.1% by mass or more, an adhesion effect can be obtained. When the proportion of the adhesion improver is 20% by mass or less, it is possible to suppress a decrease in the strength of the adhesive structure that is the cured product obtained from the curable composition for forming an adhesive structure.

### —Solvent—

The solvent is not particularly limited and may be appropriately selected according to a purpose. Examples of the solvent include, but are not limited to, terpineol, 1-methoxy-2-propanol, diethylene glycol monomethyl ether, triethylene glycol monomethyl ether, 2-methoxyethyl acetate, 2-methoxybutyl acetate, and 2-butanone. Each of these solvents may be used alone or in combination with others.

The proportion of the solvent in the curable composition for forming an adhesive structure is not particularly limited and can be appropriately selected according to a purpose. However, if the viscosity of the curable composition for forming an adhesive structure is appropriate, the solvent is preferably not added.

If the curable composition for forming an adhesive structure contains the solvent, the proportion of the solvent is preferably 1% by mass or more and 10% by mass or less, and more preferably 1% by mass or more and 5% by mass or less, with respect to the total mass of the curable composition for forming an adhesive structure. When the proportion of the solvent is 1% by mass or more, it is possible to easily manage a solvent component of the curable composition for forming an adhesive structure and lower the viscosity, so that the curable composition for forming an adhesive structure can be suitably used in an inkjet printing method. Further, when the proportion of the solvent is 10% by mass or less, it is less likely that bubbles or voids are generated at high temperatures.

—Polymerization Initiators other than Cationic Polymerization Initiator—

Examples of polymerization initiators other than the cationic polymerization initiator include, but are not limited to, photo-radical polymerization initiators. The photo-radical polymerization initiator is not particularly limited and may be appropriately selected according to a purpose. Examples of the photo-radical polymerization initiator include, but are not limited to, alkylphenone compounds, acylphosphine oxide compounds, and oxyphenyl acetic acid ester compounds. Each of these compounds may be used alone or in combination with others.

The photo-radical polymerization initiator may be appropriately synthesized or a commercially available product may be used as the photo-radical polymerization initiator. Examples of commercially available products of the photo-radical polymerization initiator include, but are not limited to, OMNIRAD 184 (former IRGACURE 184), OMNIRAD 651 (former IRGACURE 651), OMNIRAD 1173 (former IRGACURE 1173), OMNIRAD 2959 (former IRGACURE 2959), OMNIRAD 369 (former IRGACURE 369), OMNIRAD 907 (former IRGACURE 907), OMNIRAD BMS, OMNIRAD DETX, OMNIRAD TPO H (former IRGACURE TPO), OMNIRAD 819 (former IRGACURE 819) (all manufactured by IGM Resins B.V.), IRGACURE OXE01, IRGACURE OXE02, IRGACURE OXE03, and IRGACURE OXE04 (all manufactured by BASF Japan Ltd.).

The proportion of the photopolymerization initiator in the curable composition for forming an adhesive structure is not particularly limited and can be appropriately selected according to a purpose. However, the proportion of the photopolymerization initiator is preferably 0.1% by mass or more and 10% by mass or less, and more preferably 0.2% by mass or more and 2% by mass or less, with respect to the total mass of the curable composition for forming an adhesive structure. If the proportion of the photopolymerization initiator is 0.1% by mass or more and 10% by mass or less, the curing reaction can be appropriately completed, and unreacted components are less likely to remain as reactive impurities.

### (Adhesive Structure and Cured Product)

The adhesive structure of the present embodiment contains a resin including a glycidylamine-type epoxy unit and an oxetane unit, and a component derived from a cationic polymerization initiator. The proportion of the glycidylamine-type epoxy unit in the resin is 10% by mass or more. If desired, the adhesive structure contains other components.

The cured product of the present embodiment is obtained by curing the curable composition for forming an adhesive structure. Therefore, the cured product of the present embodiment has a similar configuration as the adhesive structure, and contains a resin including a glycidylamine-type epoxy unit and an oxetane unit, and a component derived from a cationic polymerization initiator. The proportion of the glycidylamine-type epoxy unit in the resin is 10% by mass or more. If desired, the cured product contains other components.

The cured product of the present embodiment will be described below, together with the description of the adhesive structure of the present embodiment. The present invention is not limited to the embodiments described below, may be another embodiment, and may be subject to changes such as additions, modifications, and omissions within the scope conceivable for a person skilled in the art. All of these changed configurations are also included in the scope of the present invention, as long as an operation and an effect of the present invention are exhibited.

The adhesive structure has the configuration described above, and thus, the adhesive performance of the adhesive structure is excellent in adhesiveness, heat resistance, and flexibility. In particular, if the adhesive structure is used to adhere two adhesion targets to each other and the two adhesion targets have different linear expansion coefficients, the adhesive structure has the advantage that adhesion and connection failures are unlikely to occur, even when the adhesive structure is used for adhesion to parts where thermal stress is generated by a heat cycle or parts used in high-temperature environments of 100° C. or higher. Further, the adhesive structure has excellent adhesiveness, heat resistance, and flexibility, even when the adhesive structure is formed into a thin film.

The adhesive structure contains a resin including the glycidylamine-type epoxy unit and the oxetane unit.

The glycidylamine-type epoxy unit is a cured product obtained by curing the glycidylamine-type epoxy compound in the curable composition for forming an adhesive structure. The oxetane unit is a cured product obtained by curing the oxetane compound in the curable composition for forming an adhesive structure. Therefore, the resin including the glycidylamine-type epoxy unit and the oxetane unit is a cured product cured by cationic polymerization of the glycidylamine-type epoxy compound and the oxetane compound.

The cured product of the glycidylamine-type epoxy compound is obtained by using the cationic polymerization initiator to open the ring of the epoxy group of the glycidylamine-type epoxy compound, and polymerizing and cross-linking the opened epoxy groups. An example of a scheme of a curing reaction of an epoxy compound using a cationic polymerization initiator is illustrated below.

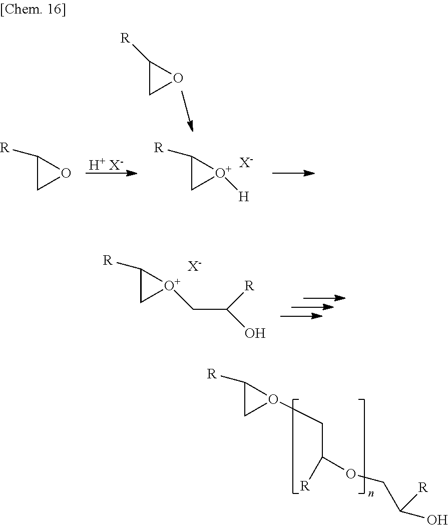

The proportion of the glycidylamine-type epoxy unit in the resin is not particularly limited and may be appropriately selected according to a purpose, but is preferably 10% by mass or more, more preferably 10% by mass or more and 40% by mass or less, and even more preferably 15% by mass or more and 30% by mass or less. When the proportion of the glycidylamine-type epoxy unit in the resin is 10% by mass or more, the adhesive structure has good heat resistance and adhesiveness.

The cured product of the oxetane compound is obtained by using the cationic polymerization initiator to open the ring of the oxetane group of the oxetane compound, and polymerizing and cross-linking the opened oxetane groups. An example of a scheme of a curing reaction of an oxetane compound using a cationic polymerization initiator is illustrated below.

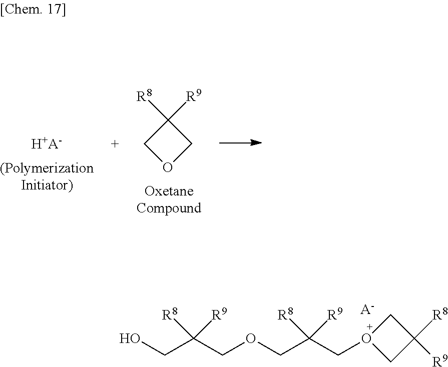

The oxetane compound in the scheme of the curing reaction of the oxetane compound is a compound represented by General Formula (3) above, in which R⁸ represents an ethyl group, R⁹ represents —CH₂—O—R⁵, and R⁵ represents a monovalent organic group.

The proportion of the oxetane unit in the resin is not particularly limited and may be appropriately selected according to a purpose. However, the proportion of the oxetane unit is preferably 10% by mass or more and 60% by mass or less, and more preferably 20% by mass or more and 40% by mass or less. When the proportion of the oxetane unit in the resin is 10% by mass or more, the adhesive structure has good flexibility, and when the proportion of the oxetane unit is 60% by mass or less, the adhesive structure has good heat resistance and adhesiveness.

In the present specification, the component derived from the cationic polymerization initiator is a cationic polymerization initiator, or ions forming a salt, when the cationic polymerization initiator is a salt, or a product having a changed chemical structure after an initiation reaction occurs. For example, if SAN-AID SI-100 (substituted arylalkylsulfonium hexafluoroantimonic acid) manufactured by Sanshin Chemical Industry Co., Ltd. is used as the cationic polymerization initiator, the component derived from the cationic polymerization initiator corresponds to SAN-AID SI-100, substituted arylalkylsulfonium ions, hexafluoroantimonate ions, or substituted arylalkylsulfides.

The proportion of the component derived from the cationic polymerization initiator in the adhesive structure is not particularly limited, and may be appropriately selected according to the cationic polymerization initiator and the like.

The adhesive structure contains the resin including the glycidylamine-type epoxy unit and the oxetane unit, and the component derived from the cationic polymerization initiator. The adhesive structure may only include an adhesion part having adhesiveness and in which the proportion of the glycidylamine-type epoxy unit in the resin is 10% by mass or more.

However, the adhesive structure preferably includes a pattern adjusting part in addition to the adhesion part, and the adhesive structure may further include a heat conducting part, and if desired, other members.

The shape of the adhesive structure can be determined by mapping analysis in a cross-sectional direction and a planar direction by using Fourier transform infrared spectroscopy (FT-IR).

### <<Adhesion Part>>

The adhesion part is a member to which the adhesion target can be adhered. The adhesion part contains the resin including the glycidylamine-type epoxy unit and the oxetane unit, and the component derived from the cationic polymerization initiator. The proportion of the glycidylamine-type epoxy compound in the resin is 10% by mass or more.

The adhesion part may contain other components contained in the curable composition for forming an adhesive structure, or a cured product of a monomer component of the other components.

The elastic modulus of the adhesion part (the elastic modulus of the adhesive structure if the adhesive structure includes only the adhesion part) is not particularly limited and may be appropriately selected according to a purpose. However, the elastic modulus of the adhesion part is preferably 500 MPa or more and 10,000 MPa or less, and more preferably 500 MPa or more and 5,000 MPa or less. When the elastic modulus of the adhesion part is 500 MPa or more, the adhesion part has excellent stiffness, and when the elastic modulus of the adhesion part is 10,000 MPa or less, the adhesion part is unlikely to be brittle and fracture.

For example, the elastic modulus of the adhesion part can be determined by using a film of the adhesion part obtained by forming a film of the adhesion part on a glass surface and curing the film, to measure the indentation elastic modulus with a microhardness tester (for example, FISCHERSCOPE (registered trademark) HM2000, manufactured by Fischer Instruments Co., Ltd.).

The glass transition temperature (Tg) of the adhesion part (the glass transition temperature (Tg) of the adhesive structure, if the adhesive structure includes only the adhesion part) is not particularly limited, and may be appropriately selected according to a purpose. However, from the viewpoint of heat resistance, the glass transition temperature of the adhesion part is preferably 80° C. or higher. When the glass transition temperature (Tg) of the adhesion part is 80° C. or higher, the adhesiveness in a high-temperature environment is excellent.

For example, the glass transition temperature (Tg) of the adhesion part can be measured as follows. The curable composition for forming an adhesive structure is injected between two glass plates. Subsequently, the glass plates are heated to cure the curable composition. After that, a sample is prepared by peeling the cured product from the glass, and the glass transition temperature is measured by a rheometer (ARES-G2, manufactured by TA Instruments) under the following measurement conditions.

### [Measurement Conditions]

Measurement method: Torsion vibration
Measurement sample set: tension of 10 gf (Gap variable: initial value of about 10 mm)
Strain conditions: minimum torque of 0.3 g-cm (variable strain: initial value of 0.05%, maximum value of 1%)
Temperature: from 25° C. to 300° C., at 20° C./minute
Shape of sample: about 20 mm×5 mm (thickness: 100 μm)

### —Adhesion Target—

The adhesion target is not particularly limited and may be appropriately selected according to a purpose. Examples of the adhesion target include, but are not limited to, a heat-generating component, a cooling component, a substrate, and an electrode.

The heat-generating component is not particularly limited and may be appropriately selected according to a purpose. Examples of the heat-generating component include, but are not limited to, a semiconductor (die), a semiconductor package (IC chip), a battery, an LED, a capacitor, a resistor, and a diode. Among these, the heat-generating component is preferably a semiconductor or a semiconductor package (IC chip), which preferably has reliable heat resistance in adhesion or connection processes in a mounted circuit at increased temperatures in accordance with high integration and high speed in recent years.

The cooling component is not particularly limited and may be appropriately selected according to a purpose. However, the cooling component is preferably a component that cools the heat of the heat-generating component by air cooling, liquid cooling, phase-change cooling, thermoelectric cooling, or the like. Specific examples of the cooling component include, but are not limited to, a heat sink, a heat pipe, a microchannel, a Peltier element, a heat dissipation sheet, and a heat spreader.

The substrate is not particularly limited and may be appropriately selected according to a purpose. Examples of the substrate include, but are not limited to, PCB/PWB/BGA substrates (glass-epoxy substrates, ceramic substrates such as alumina oxide substrates, copper substrates, polyimide substrates), and lead frames.

The electrode is not particularly limited and may be appropriately selected according to a purpose. Examples of the electrode include, but are not limited to, metals such as Au, Ag, Pd, Cu, Ni, Pt, Fe, and Co, and solder materials such as Sn/Pb and Sn/Ag/Cu.

### <<Pattern Adjusting Part>>

The pattern adjusting part is a member that adjusts and controls a shape of the coating pattern of the adhesion part. The pattern adjusting part preferably contains a photocurable resin.

The adhesive structure includes the pattern adjusting part, and thus, it is possible to control wet spreading and the thickness of the curable composition for forming an adhesive structure for forming the adhesion part, and it is possible to improve the accuracy when forming the adhesion part by pattern forming.

The shape of the pattern adjusting part is not particularly limited, as long as the shape of the coating pattern of the adhesion part can be adjusted and controlled. However, to control wet spreading and the thickness of the curable composition for forming an adhesive structure for forming the adhesion part, the pattern adjusting part is preferably formed on the outer periphery of the adhesion part (is formed in a configuration that forms an outer frame of the shape of the adhesion part), but the pattern adjusting part may also be formed inside the adhesion part (in a thickness direction and/or a planar direction).

The volume of the pattern adjusting part in the adhesive structure is not particularly limited and may be appropriately selected according to a purpose, but is preferably 50% by volume or less of the volume of the adhesion part. When the volume of the pattern adjusting part is 50% by volume or less of the volume of the adhesion part, the adhesiveness of the adhesive structure can be easily maintained.

Further, it is preferable that the pattern adjusting part is formed as a low-elasticity part that suppresses thermal deformation stress. As used herein, the term “low-elasticity part” refers to a part having an elastic modulus that is smaller than that of the adhesion part.

When the pattern adjusting part is a low-elasticity part, the elastic modulus of the pattern adjusting part is not particularly limited and may be appropriately selected according to a purpose, as long as the elastic modulus of the pattern adjusting part is lower than that of the adhesion part. However, the elastic modulus of the pattern adjusting part is preferably 80% or less of the elastic modulus of the adhesion part, and more preferably 50% or less of the elastic modulus of the adhesion part. Specifically, if the pattern adjusting part is a low-elasticity part, the elastic modulus of the pattern adjusting part is preferably 3,000 MPa or less, and more preferably 2,000 MPa or less. If the elastic modulus of the pattern adjusting part is smaller, the stress relaxation effect increases.

For example, the elastic modulus of the pattern adjusting part can be determined by using a film of the pattern adjusting part obtained by forming a film of the pattern adjusting part on a glass surface and curing the film, to measure the indentation elastic modulus with a microhardness tester (for example, FISCHERSCOPE (registered trademark) HM2000, manufactured by Fischer Instruments Co., Ltd.).

### <<Heat Conducting Part>>

The heat conducting part is a member formed continuously in the thickness direction in the adhesive structure. The heat conducting part has a function of conducting heat in the thickness direction. Therefore, if the heat conducting part is formed by pattern forming in the adhesive structure, heat conduction characteristics, heat dissipation characteristics, and electrical conduction characteristics can be improved between top and bottom portions of the adhesive structure in the thickness direction.

Therefore, if the adhesive structure is used to adhere a heat-generating component, a cooling component, an electrode, and the like, the adhesive structure preferably includes the heat conducting part.

The outer peripheral shape of the heat conducting part surrounded by the adhesion part and/or the pattern adjusting part is not particularly limited and may be appropriately selected according to a purpose. Examples of the outer peripheral shape include, but are not limited to, any combination of shapes including straight lines, circular arcs, and elliptical arcs.

In the adhesive structure, the shape and the size of the heat conducting part that is exposed on one surface may be the same as or different from the shape and the size of the heat conducting part that is exposed on the other surface.

The thickness of the heat conducting part is basically set to be the same as the thickness of the adhesion part and the pattern adjusting part, while the area (volume) of the heat conducting part is set to an optimum value according to a heat dissipation design.

If carbon nanoparticle ink or graphene ink is used as a carbon material to form a coating, the thickness of the heat conducting part is preferably 1 μm or more and 300 μm or less. If the ceramic material is used as a ceramic paste obtained by mixing ceramic particles and a resin and a coating of the ceramic paste is formed, the thickness of the heat conducting part is preferably 1 μm or more and 500 μm or less.

The shape of the adhesive structure is not particularly limited, can be appropriately selected according to a purpose, and may be a layered shape or a block shape.

The term “layered shape” as used herein refers to a shape having a thickness of 1,000 μm or less, and the term “block shape” refers to a shape having a thickness of more than 1,000 μm. These shapes may be appropriately selected according to an intended usage. For example, an adhesive structure having a layered shape can be suitably used to adhere a semiconductor (die) that is preferably formed as a thin film, to various types of materials to be adhered to the semiconductor (die).

If the adhesive structure has a layered shape, the thickness of the adhesive structure is 1,000 μm or less, but preferably 1 μm or more and 500 μm or less, and more preferably 1 μm or more and 50 μm or less from the viewpoint of reducing the thickness and reducing thermal resistance. From the viewpoint of heat dissipation, the thickness of the adhesive structure is even more preferably 1 μm or more and 30 μm or less, and particularly preferably 1 μm or more and 20 μm or less. If the thickness of the adhesive structure is 1 μm or more and 30 μm or less, the heat dissipation of heat-generating components is improved, and the thickness of a semiconductor device can be reduced, when the adhesive structure is used to adhere heat-generating components (for example, semiconductors).

The thickness of the adhesive structure can be measured by using a stylus meter (ALPHA-STEP D-500, manufactured by KLA-Tenchore), an optical reflectance spectrometer-type measurement instrument (F50, manufactured by Filmetrics Inc.), or the like. The term “thickness” as used herein refers to an “average thickness” obtained by measuring the thickness at any three locations with the stylus meter and calculating an average of the three values.

The method of manufacturing the adhesive structure is not particularly limited, but the adhesive structure is suitably manufactured by a method of manufacturing an adhesive structure of the present embodiment.

Next, the adhesive structure of the present embodiment will be described in detail with reference to the drawings, but the adhesive structure of the present embodiment is not limited thereto.

As described above, the adhesive structure contains the resin including the glycidylamine-type epoxy unit and the oxetane unit, and the component derived from the cationic polymerization initiator. Further, the adhesive structure includes an adhesion part 1 in which the proportion of the glycidylamine-type epoxy unit in the resin is 10% by mass or more. Further, the adhesive structure may further include a pattern adjusting part 2 that supports pattern formation of the adhesion part 1 and a heat conducting part 3 that is continuously formed in the thickness direction of the adhesion part 1.

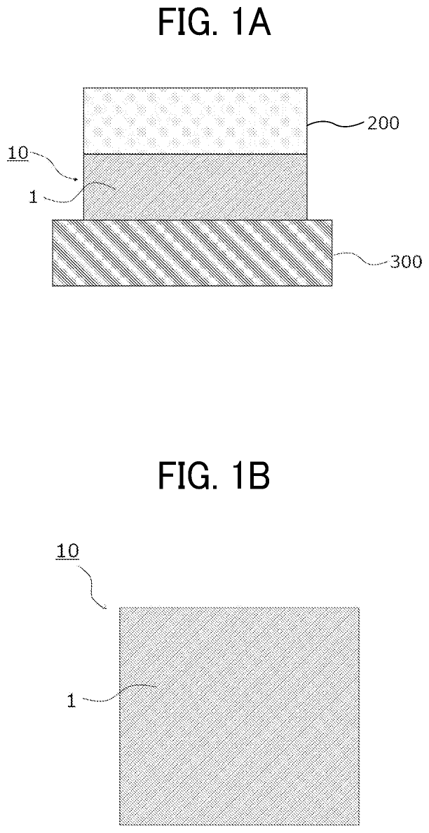

FIG. 1A is a schematic cross-sectional view in a film thickness direction of a first example of the adhesive structure of the present embodiment (an X-direction view passing through the center of the Y-axis in a schematic plan view). FIG. 1B is a schematic plan view (top view) of the first example of the adhesive structure of the present embodiment. In the drawings, a vertical direction is the Y-axis, and a horizontal direction is the X-axis. An adhesion layer 10 of the present embodiment is formed by the adhesion part 1 that is formed by being adhered to a contact surface by thermal curing or photocuring, or by thermal curing and photocuring. The adhesion part 1 includes a resin including at least a glycidylamine-type epoxy unit and an oxetane unit, and a component derived from a cationic polymerization initiator. If photocuring is used, a photo-cationic polymerization initiator is added to the glycidylamine-type epoxy compound and the oxetane compound. If thermal curing is used, a thermal cationic polymerization initiator is added to the glycidylamine-type epoxy compound and the oxetane compound. If thermal curing and photocuring are used, the curable composition for forming an adhesive structure is prepared by adding a photo-cationic polymerization initiator and a thermal cationic polymerization initiator. Subsequently, the curable composition for forming an adhesive structure is coated to a substrate or a heat-generating component at a desired thickness, and then, the heat-generating components or the substrates are attached to each other and the curable composition is cured to adhere the heat-generating components or the substrates to each other. The adhesion part 1 contains at least a resin including a glycidylamine-type epoxy unit and an oxetane unit, and a component derived from a cationic polymerization initiator. The proportion of the glycidylamine-type epoxy compound in the resin is 10% by mass or more, so that an adhesive function is maintained even at high temperatures, and the adhesion part 1 has thermal stress (strain) resistance. FIG. 1A illustrates an example in which the curable composition for forming an adhesive structure is applied at a desired thickness to a substrate 300 for a printed wiring board (BGA), and then, a semiconductor (silicon chip) substrate 200 is attached to the substrate 300 and the curable composition is cured to adhere the substrate 200 and the substrate 300 to each other.

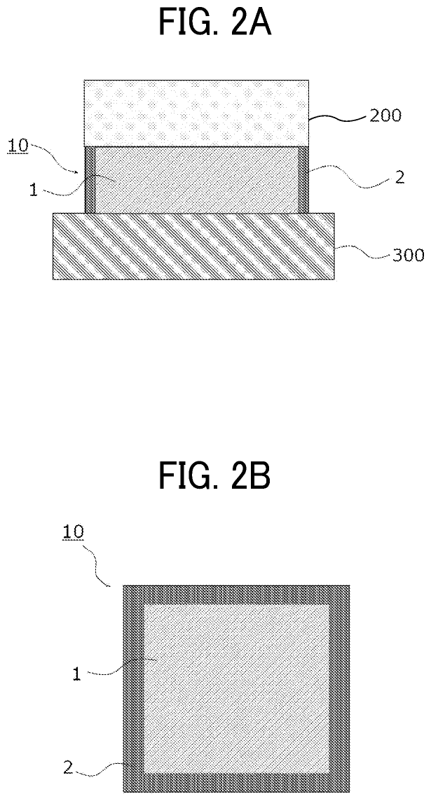

FIG. 2A is a schematic cross-sectional view in a film thickness direction of a second example of the adhesive structure of the present embodiment (an X-direction view passing through the center of the Y-axis in a schematic plan view). FIG. 2B is a schematic plan view (top view) of the second example of the adhesive structure of the present embodiment. In the drawings, the vertical direction is the Y-axis, and the horizontal direction is the X-axis.

The second example of the adhesive structure is different from the first example of the adhesive structure in that the pattern adjusting part 2 is formed in an outer peripheral part of an adhesion surface.

In the structure of the second example of the adhesive structure, the pattern adjusting part 2 in the outer peripheral part is formed by photocuring or thermal curing, or by photocuring and thermal curing, and the adhesion part 1 that is cured by thermal curing is formed inside the pattern adjusting part 2. Therefore, the thickness of the adhesive structure can be easily adjusted and the pattern of the adhesive structure can be easily formed. In the second example of the adhesive structure, as illustrated in FIG. 2B, an example in which the pattern adjusting part 2 is formed in a rectangular shape at an outer peripheral edge part of the adhesion part 1 is illustrated. However, any shape can be adopted, as long as the pattern adjusting part 2 functions as a wall for adjusting a forming region (pattern) of the adhesion part 1 or as a wettability control part.

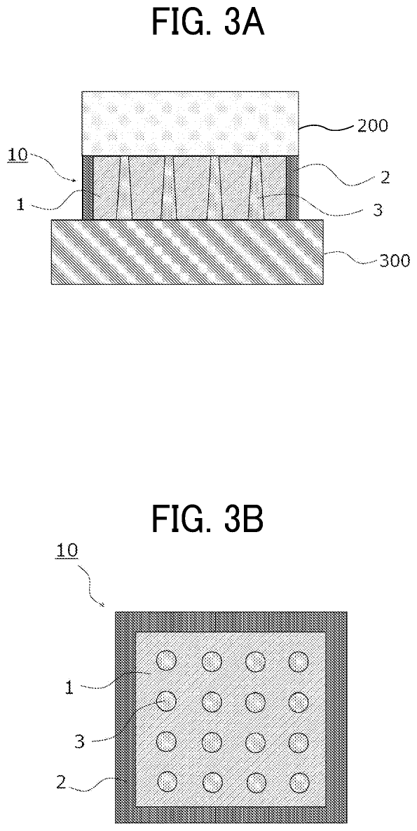

FIG. 3A is a schematic cross-sectional view in a film thickness direction of a third example of the adhesive structure of the present embodiment (an X-direction view passing through the center of the Y-axis in a schematic plan view). FIG. 3B is a schematic plan view (top view) of the third example of the adhesive structure of the present embodiment.

The third example of the adhesive structure is different from the second example of the adhesive structure in that the heat conducting part 3 formed continuously in the thickness direction is formed in a rectangular frame of the pattern adjusting part 2 in the adhesion part 1.

According to the configuration of the third example of the adhesive structure, a heat dissipation effect can be imparted by forming the heat conducting part 3. Further, if the heat conducting part 3 is formed of a metal material or a carbon material, and the heat conducting part 3 also has electrical conductivity, both a heat dissipation effect and an electric conduction effect can be imparted.

### (Method of Manufacturing Adhesive Structure)

The method of manufacturing an adhesive structure of the present embodiment is not particularly limited, as long as the curable composition for forming an adhesive structure of the present embodiment is used. However, the method preferably includes a step of applying the curable composition for forming an adhesive structure, and may include other steps if desired.

If the adhesive structure includes the adhesion part formed by the curable composition for forming an adhesive structure, the pattern adjusting part, and the heat conducting part, the method preferably includes an adhesion part forming step, a pattern adjusting part forming step, and a heat conducting part forming step.

The step of applying the curable composition for forming an adhesive structure is performed by a method similar to the adhesion part forming step.

### <<Adhesion Part Forming Step>>

The adhesion part forming step is a step of forming an adhesion part that can adhere to an adhesion target. In the adhesion part forming step, it is preferable that the curable composition for forming an adhesive structure of the present embodiment is used, and the curable composition for forming an adhesive structure is discharged from a nozzle, to be applied to the adhesion target and polymerized. If the adhesive structure includes the pattern adjusting part, it is preferable to form the adhesion part to be adjacent to the pattern adjusting part. In the adhesion part forming step, the curable composition for forming an adhesive structure is used as an ink for forming the adhesion part (adhesion part forming ink).

The coating method of the adhesion part is not particularly limited and may be appropriately selected according to a purpose. Various types of printing methods such as a spray coating method, a nozzle coating method, a dispense coating method, a gravure printing method, a screen printing method, a flexographic printing method, an offset printing method, a reverse printing method, and an inkjet printing method can be used. Among these, in the spray coating method, the dispense coating method, and the inkjet printing method, by which it is possible to form a pattern without using a printing plate and form a coating film in a non-contact manner, the adhesion part can be directly coated on a formation surface of the adhesion target. Therefore, these methods are preferable in that it is possible to form a thin film of the adhesion part (adhesive structure) and the productivity is high, compared to a method of cutting and attaching an adhesion part (adhesive structure) prepared in advance. By using these coating methods, even if the adhesive structure includes a pattern adjusting part or a heat conducting part other than the adhesion part, it is possible to apply a desired coating in accordance with these patterns. Further, the inkjet printing method is particularly preferable as the coating method of the adhesion part, because in the inkjet printing method, a very fine pattern can be formed and a thin film is formed with excellent uniformity.

If the adhesion part is formed by discharging the curable composition for forming an adhesive structure by the inkjet printing method, deposited droplets of the curable composition for forming an adhesive structure may be superimposed to form a thick film.

In this case, the curable composition for forming an adhesive structure may be laminated as the adhesion part adjacent to any one of a pattern adjusting part forming composition for forming the pattern adjusting part described later and a heat conducting part forming composition for forming the heat conducting part described later that are deposited before the curable composition for forming an adhesive structure. Alternately, the curable composition for forming an adhesive structure may be alternately deposited with a composition (ink) selected from the pattern adjusting part forming composition and the heat conducting part forming composition to be adjacent to the selected composition in a laminated structure. Thus, it is possible to form the adhesion part having any shape by pattern forming, without forming the adhesion part by photocuring. Further, the curable composition for forming an adhesive structure does not need to be cured by photocuring or the desired performance of photocuring is lowered, so that it possible to select a material for the curable composition for forming an adhesive structure that has optimal thermal curing properties and adhesiveness.

To further improve the pattern accuracy of the adhesion part, it is possible to use a method of forming a pattern while photocuring the adhesion part. That is, the accuracy of pattern forming can be improved by photocuring droplets obtained by applying the curable composition for forming an adhesive structure by patterning coating, before the droplets spread when time elapses. In photocuring, a method is adopted in which a semi-cured state is formed, and/or photocured droplets are laminated, and only an outermost droplet surface that forms the contact surface is not photocured, so that it possible to maintain the adhesiveness of the adhesion surface (outermost droplet surface) when attaching components.

In particular, if an inkjet printing system in which a UV LED array is mounted to an inkjet head is used, it is possible to form patterns with high accuracy by immediately curing deposited droplets with UV LED after jetting. The ink applied in inkjet printing is discharged from a nozzle having a small diameter, and thus, ink having a low viscosity of about 5 mPa·s or more and 200 mPa·s or less is generally suitable.

If a pattern is formed by such photocuring, the curable composition for forming an adhesive structure preferably contains both the photo-cationic polymerization initiator and the thermal cationic polymerization initiator. Thus, when a coating film is formed by pattern forming, the accuracy of the pattern forming can be improved by photocuring, and the adhesiveness can be improved by thermal curing after components are attached.

### <<Pattern Adjusting Part Forming Step>>

The pattern adjusting part forming step is a step of forming a pattern adjusting part that adjusts and controls the shape of the coating pattern of the adhesion part.

In the pattern adjusting part forming step, a pattern adjusting part is preferably formed by pattern forming using a pattern adjusting part forming composition for forming the pattern adjusting part. The pattern adjusting part forming composition is preferably discharged from a nozzle, applied to an adhesion target, and polymerized. Further, it is preferable that the pattern adjusting part is formed to be adjacent to the adhesion part.

The order in which the pattern adjusting part forming step is performed is not particularly limited and may be appropriately selected according to a purpose. However, the pattern adjusting part forming step is preferably performed before the adhesion part forming step. Thus, the pattern adjusting part or a part thereof can be formed by the pattern adjusting part forming step before the adhesion part forming step, and in the adhesion part forming step, it is possible to suitably control wet spreading and the thickness of the curable composition for forming an adhesive structure.

As used herein, “pattern forming” (also referred to as “patterning”) refers to a method of selectively arranging the adhesion part in a predetermined position and shape. Therefore, the term “pattern forming” refers to at least any one of forming a sparse and dense distribution of the adhesion part and the pattern adjusting part in a thickness direction of the adhesive structure and/or a planar direction (a direction substantially perpendicular to the thickness direction); and intentionally (artificially) forming the adhesion part and the pattern adjusting part into a desired shape in the adhesive structure. Thus, the term “pattern forming” does not include a sea-island structure that is unintentionally (spontaneously) formed into any shape. The sea-island structure may be caused by the method of manufacturing the adhesive structure, and the pattern forming can be realized by the method of manufacturing the adhesive structure.

The coating method of the pattern adjusting part is not particularly limited and may be appropriately selected from known methods. Examples of the coating method include, but are not limited to, a spin coating method, a casting method, a micro gravure coating method, a bar coating method, a roll coating method, a wire bar coating method, a dip coating method, a slit coating method, a capillary coating method, an inkjet printing method, a spray coating method, a nozzle coating method, a dispense coating method, a gravure coating method, a screen printing method, a flexographic printing method, an offset printing method, and a reverse printing method. Among these, the spray coating method, the dispense coating method, and the inkjet printing method are preferable because by these methods, it is possible to form a pattern without using a printing plate and form a coating film in a non-contact manner. By these coating methods, it is possible to perform desired coating in accordance with the patterns of the pattern adjusting part and the adhesion part. Further, the inkjet printing method is particularly preferable as the coating method of the pattern adjusting part, because in the inkjet printing method, a very fine pattern can be formed and a thin film is formed with excellent uniformity.

If the pattern adjusting part forming composition is used, it is possible to perform patterning coating while maintaining excellent filling properties in wiring parts of wire bonds, flip chips, and the like, and advantageously suppress the generation of bubbles and voids, which are starting points for peeling of the adhesive structure.

To improve the pattern accuracy of the pattern adjusting part, a method of forming a pattern while photocuring the pattern adjusting part can be used, similarly as in the adhesion part forming step.

That is, the accuracy of pattern forming can be improved by photocuring droplets obtained by applying the curable composition for forming an adhesive structure by pattern coating, before the droplets spread when time elapses.

If a pattern is formed by such photocuring, the pattern adjusting part forming composition preferably contains both the photopolymerization initiator and the thermal polymerization initiator. Thus, when a coating film is formed by pattern forming, the accuracy of the pattern forming can be improved by photocuring, and the adhesiveness can be improved by thermal curing after components are attached.

### —Pattern Adjusting Part Forming Composition—

In the pattern adjusting part forming step, the pattern adjusting part forming composition is used as ink for forming the pattern adjusting part (pattern adjusting part forming ink). The material of the pattern adjusting part forming composition that forms the pattern adjusting part is not particularly limited. However, from the viewpoint of the adhesiveness and the adhesive properties between the adhesion part and the pattern adjustment part, it is preferable to use a material similar to the curable composition for forming an adhesive structure, and it is more preferable that the material contains a monomer of a photocurable resin.

The monomer of the photocurable resin may be used alone as the pattern adjusting part forming composition and cured to form the pattern adjusting part. However, the pattern adjusting part forming composition preferably contains the monomer of the photocurable resin and a monomer of a heat-curable resin, and this composition is cured to form the pattern adjusting part, because in this case, the pattern adjustment and the adhesion performance can be suitably imparted.

Specific examples of the material of the pattern adjusting part forming composition include, but are not limited to, the glycidylamine-type epoxy compound, the oxetane compound, the monomer other than the glycidylamine-type epoxy compound and the oxetane compound, the silicone compound, the inorganic particles, the resin and/or the resin particles, the adhesion improver, and the cationic polymerization initiator. Each of these may be used alone or in combination with others. As the material of the pattern adjusting part forming composition, a material similar to the curable composition for forming an adhesive structure can be used, and thus, description thereof will be omitted.

The physical properties such as the viscosity of the pattern adjusting part forming composition are similar to those of the curable composition for forming an adhesive structure, and thus, description thereof will be omitted.

The pattern adjusting part may be a cured product (pattern adjusting part) that has excellent flexibility in which the elastic modulus is lower than in the adhesion part by the material type and the mixing ratio of the pattern adjusting part forming composition being used.

Specifically, it is preferable to use, as the ink material type of the pattern adjusting part forming composition, an ink to which at least one selected from the glycidylamine-type epoxy compound, the oxetane compound, the glycidyl ether-type epoxy compound, the (meth)acrylate monomer, the urethane monomer, and the resin and/or the resin particles is mixed.

Further, in the pattern adjusting part forming composition, the proportion of the oxetane compound, the proportion of the glycidyl ether-type epoxy compound, the proportion of the (meth)acrylate monomer, the proportion of the urethane monomer, and the proportion of the resin and/or the resin particles may be higher than in the curable composition for forming an adhesive structure. Thus, it is easily possible to prepare the pattern adjusting part forming composition in which the cured product has a lower elasticity than the cured product of the curable composition for forming an adhesive structure.

Commercially available photocurable and heat-curable inkjet solder resist inks may also be used as the pattern adjusting part forming composition.

Specific examples of the commercially available photocurable and heat-curable inkjet solder resist inks include, but are not limited to, IJSR4000, IJSR9000 (manufactured by TAIYO INK MFG Co., Ltd.), PR1205, PR1243, PR1258 (manufactured by GOO Chemical Co., Ltd.), SUN-004, SUN-013A, SUN-015, C-202, C-400, E635A, E800D (all manufactured by Sekisui Chemical Co., Ltd.), and jSVR (manufactured by Dexerials Corporation).

### <<Heat Conducting Part Forming Step>>

In the heat conducting part forming step, a heat conducting part forming composition for forming the heat conducting part is preferably used to form the heat conducting part by pattern forming. The heat conducting part forming composition is preferably discharged from a nozzle to form the heat conducting part that is continuous in the thickness direction of the adhesive structure, and further, the heat conducting part is preferably polymerized. It is preferable that the heat conducting part is formed to be adjacent to at least one of the adhesion part and the pattern adjusting part.

The order in which the heat conducting part forming step is performed is not particularly limited and may be appropriately selected according to a purpose. However, to improve the pattern accuracy of the heat conducting part, it is preferable that the heat conducting part forming step is performed by dripping the heat conducting part forming composition between the adhesion part and/or the pattern adjusting part after at least the adhesion part and/or the pattern adjusting part are formed by pattern forming in the adhesion part forming step or the pattern adjusting part forming step, respectively. Thus, the adhesion part and/or the pattern adjusting part pattern that are formed by pattern forming with high accuracy are utilized to improve the accuracy of the pattern coating of the heat conducting part in heat conducting part forming step.

### —Heat Conducting Part Forming Composition—

In the heat conducting part forming step, the heat conducting part forming composition is used as ink for forming the heat conducting part (heat conducting part forming ink). The material of the heat conducting part forming composition forming the heat conducting part is not particularly limited and may be appropriately selected according to a purpose, but the material preferably contains a thermally conductive material, and further contains other components if desired.

### —Thermally Conductive Material—

The thermally conductive material is not particularly limited and may be appropriately selected according to the purpose. Examples of the thermally conductive material include, but are not limited to, a metal material, carbon, and a ceramic material.

Examples of the metal material include, but are not limited to, silver (Ag), copper (Cu), gold (Au), and aluminum (Al).

Examples of the ceramic material include, but are not limited to, silica (SiO₂), aluminum oxide (Al₂O₃), aluminum nitride (AlN), and boron nitride (BN).

Each of these materials may be used alone or in combination with others. Among these, the thermally conductive material is preferably a metal material, and more preferably metal nanoparticles. The metal material can also be used as an electrically conductive material.

The primary average particle diameter (D50) of the thermally conductive material in the heat conducting part forming composition is not particularly limited and may be appropriately selected according to a purpose, but is preferably 0.01 μm or more and 100 μm or less, and more preferably 0.3 μm or more and 10 μm or less.

The primary average particle diameter (D50) of the thermally conductive material can be measured by a dynamic image analysis method, a dynamic light scattering method (DLS), and the like.

The primary average particle diameter (D50) of the metal nanoparticles in the heat conducting part forming composition is not particularly limited and may be appropriately selected according to a purpose, but is preferably 0.005 μm or more and 1 μm or less, and more preferably 0.005 μm or more and 0.2 μm or less. If the primary average particle diameter (D50) of the metal nanoparticles is 0.005 μm or more and 1 μm or less, when the adhesive structure is used to adhere a heat-generating component or a cooling component, it is possible to form a heat conducting part having high heat conductivity in which unevenness of a contact surface between the adhesive structure and the heat generating component or the cooling component is small, and the contact surface is flat and integrally formed. The primary average particle diameter (D50) of the metal nanoparticles is preferably 200 nm or less, so that sintering can be performed by a process at a relatively low temperature of about 150° C. Further, if the metal nanoparticles have a small particle diameter, it is possible to reduce the film thickness of the heat conducting part and perform precise patterning by inkjet printing coating using a nozzle having a small diameter.

The primary average particle diameter (D50) of the metal nanoparticles can be measured by a dynamic image analysis method, a dynamic light scattering method (DLS), and the like.

The proportion of the thermally conductive material (excluding the solvent component) in the heat conducting part forming composition is not particularly limited and may be appropriately selected according to a purpose, but is preferably 15% by mass or more and 100% by mass or less, and more preferably 40% by mass or more and 100% by mass or less, with respect to the total mass of the heat conducting part forming composition. If the proportion of the thermally conductive material in the heat conducting part forming composition is in a range of 15% by mass or more and 100% by mass or less, high thermal conductivity can be obtained.

The coating method using the carbon material and the coating method using the ceramic paste are not particularly limited and may be appropriately selected according to a purpose. Examples of the coating methods include, but are not limited to, a spin coating method, a casting method, a micro gravure coating method, a gravure coating method, a bar coating method, a roll coating method, a wire bar coating method, a dip coating method, a slit coating method, a capillary coating method, a spray coating method, a nozzle coating method, a dispense coating method, and various types of printing methods such as a gravure printing method, a screen printing method, a flexographic printing method, an offset printing method, a reverse printing method, and an inkjet printing method.

If the heat conducting part forming composition contains a monomer and a polymerization initiator, the ink can be cured by light or heat after coating.

If the heat conducting part is formed by the inkjet printing method, a dispersion ink of a metal material, carbon, and a ceramic material is preferably used. By using the dispersion ink, it is possible to adjust the viscosity to an ink viscosity suitable for inkjet discharge.

The viscosity of the dispersion ink is not particularly limited and may be appropriately selected according to a purpose, but is preferably 5 mPa·s or more and 200 mPa·s, so that the viscosity is suitable for inkjet discharge.

The viscosity of the dispersion ink can be measured by a method similar to the method used for measuring the viscosity of the curable composition for forming an adhesive structure.

In the dispersion ink, a solvent can be used as the dispersion solvent, or a monomer having low viscosity can be used as the dispersion solvent. As the material of the dispersion solvent, a material similar to the solvent in the curable composition for forming an adhesive structure can be used.

The proportion of the thermally conductive material in the dispersion ink is not particularly limited and may be appropriately selected according to a purpose, but is preferably 15% by mass or more and 80% by mass or less, with respect to the total amount of the dispersion ink. If the proportion of the thermally conductive material in the dispersion ink is 15% by mass or more, it is easy to obtain a heat conduction effect, and if the proportion of the conductive material is 80% by mass or less, the viscosity can be reduced, and such an ink can be suitably used for an inkjet printing method.

### —Other Components—

The other components in the heat conducting part forming composition are not particularly limited, may be appropriately selected according to a purpose, and examples thereof include, but are not limited to, resins, monomers, polymerization initiators, solvents, and dispersants.

As the resin, the monomer, the polymerization initiator, and the solvent, materials similar to those of the curable composition for forming an adhesive structure can be used, and the preferred aspects are also similar, so that the description thereof will be omitted. The preferred aspects of the solvent and the monomer when used as the dispersion ink are as described above.

### —Dispersant—

The dispersant is not particularly limited and may be appropriately selected according to a purpose. Examples of the dispersant include, but are not limited to, a polyfunctional comb-shaped functional polymer having an ionic group as a main chain and a polyoxyalkylene chain as a graft chain. The ionic group functions as an adsorptive group on the powder surface, and the graft chain controls solubility in the solvent and provides a steric repulsion effect.

Specific examples of the dispersant include, but are not limited to, alkylthiols such as dodecanethiol, and polyvinylpyrrolidone polymers. Each of these dispersants may be used alone or in combination with others.

The dispersant may be appropriately synthesized or a commercially available product may be used as the dispersant. Examples of commercially available products of the dispersant include, but are not limited to, MALIALIM (registered trademark), MALIALIM SC (registered trademark), MALIALIM FA (registered trademark), ESLEAM C (registered trademark), ESLEAM MP (registered trademark), ESLEAM AD (registered trademark)), and ESLEAM 221P (registered trademark) (manufactured by NOF Corporation).

The proportion of the other components in the heat conducting part forming composition is not particularly limited and may be appropriately selected according to a purpose, but the solid proportion of the resin, the dispersant, a cured monomer product, and the like is preferably 5% by mass or less. Thus, the solid proportion is removed by decomposition or gasification during sintering, so that it is possible to form a heat conducting part in which the proportion of the thermally conductive material in the heat conducting part is 95% by mass or more.

The heat conducting part forming composition may be appropriately synthesized or a commercially available product may be used as the heat conducting part forming composition. If the thermally conductive material contains a metal material, a method of reducing and depositing a metal solution ink can be used in addition to the method of using the ink containing the metal material. The metal solution ink is generally known as silver salt ink, and such an ink can also be used.

Examples of commercially available products of the heat conducting part forming composition include, but are not limited to, the commercially available products listed in Table 1 below. Each of these products may be used alone or in combination with others.

TABLE 1

| | | | Metal | Particle |
|---|---|---|---|---|
| Metal | | | proportion | diameter |
| species | Manufacturer | Product name | (wt %) | (nm) |
| Ag | DAICEL | PICOSIL | 50 | 20-30 |
| particles | | DNS0150I | | |
| | DAICEL | PICOSIL | 60-70 | <200 |
| | | DNS0404P | | |
| | DAICEL | PICOSIL | 67-78 | <200 |
| | | DNS0215P | | |
| | GenesInk | SMART INK | 20 | <100 |
| | | Smart Jet I (S- | | |
| | | CS01520) | | |
| | PVnanocell | SICRYS | 40 | 70 |
| | | I40DM-106 | | |
| | PVnanocell | SICRYS | 50 | 80 |
| | | I50DM-106 | | |
| | PVnanocell | SICRYS | 50 | 70 |
| | | I50TM-115 | | |
| | PVnanocell | SICRYS | 50 | 70 |
| | | I50TM-119 | | |
| | PVnanocell | SICRYS I50T- | 50 | 70 |
| | | 13 | | |
| | ULVAC | L-Ag1TeH | 50-60 | 3-7 |
| | Bando | FlowMetal ® | 40 | 23-33 |
| | Chemical | SW1020 | | |
| | Industries | | | |
| | Bando | FlowMetal ® | 60 | 30 |
| | Chemical | SR7000 | | |
| | Industries | | | |
| | Bando | FlowMetal ® | 50 | 30 |
| | Chemical | SR7500 | | |
| | Industries | | | |
| | Future Ink | F-NANO | 50 | 160 |
| | | IJ100GE | | |
| | Future Ink | F-NANO | 37 | 16 |
| | | IJ200GE | | |
| | Nova Centrix | METALON JS- | 40 | 30-50 |
| | | A101A | | |
| | Nova Centrix | METALON JS- | 40 | 30-50 |
| | | A102A | | |
| | Nova Centrix | METALON JS- | 40 | 30-50 |
| | | A191 | | |
| | Kishu Giken | AGK101, | 35 | <200 |
| | Kogyo | AGK102 | | |
| | Kishu Giken | AGK103, | 65 | <200 |
| | Kogyo | AGK104 | | |
| | C-INK | DryCure ® Ag-J | 10 | <200 |
| | | 0410B, 1010B | | |
| | C-INK | DryCure ® Ag-J | 20 | <200 |
| | | 0420B, 1020B | | |
| Silver | Electroninks | EI-710 Ink | 12 | |
| salt | InkTec | TEC-IJ-010 | 15 | |
| Cu | ISHIHARA | IJ-02 | 35-45 | <70 |
| particles | CHEMICAL | | | |
| | ISHIHARA | IJ-02A | 35-45 | <70 |
| | CHEMICAL | | | |
| | PVnanocell | SICRYS | 50 | 50 |
| | | IC50DM-7 | | |
| | PVnanocell | SICRYS | 50 | 50 |
| | | IC50TM-8 | | |
| | FUKUDA | DC-50 | 20 | 50 |
| | METAL FOIL | | | |
| | & POWDER | | | |
| | Nova Centrix | METALON CI- | 20 | <200 |
| | | 004 | | |
| | Nova Centrix | METALON CI- | 26 | <200 |
| | | 005 | | |
| Au | C-INK | DryCure ® Au-J | 10 | <200 |
| particles | | 0410B, 1010B | | |

### <<Other Steps>>

The other steps in the method of manufacturing an adhesive structure are not particularly limited and may be appropriately selected according to a purpose. Examples of the other steps include, but are not limited to, a sintering step.

### —Sintering Step—

The sintering step is a step of sintering the metal nanoparticles after the heat conducting part forming step. Therefore, the sintering step is suitably performed in a case where the heat conducting part forming composition contains metal nanoparticles in the heat conducting part forming step.

The method used in the sintering is not particularly limited and may be appropriately selected from known methods. Examples of the method include, but are not limited to, a method of sintering by using heat or light. Thus, it is possible to form a heat conducting part having high thermal conductivity in which the metallic nanoparticles are sintered.

The step of sintering the heat conducting part forming composition can also serve as at least one of heat curing steps of the curable composition for forming an adhesive structure and the pattern adjusting part forming composition, for example, as a step of attaching the adhesive structure to an adhesion target.

The composition of materials in the adhesive structure can be analyzed by pyrolysis gas chromatography-mass spectrometry (GC/MS) and real-time mass spectrometry (DART-MS).

### (Semiconductor Device and Manufacturing Method Thereof)

The semiconductor device of the present embodiment includes a semiconductor, an adhesion layer, and a substrate, and if desired, further includes other layers such as an intermediate layer, and other members such as heat-generating components other than the semiconductor and cooling components. The adhesion layer is formed by the adhesive structure of the present embodiment.

The semiconductor device includes the adhesive structure of the present embodiment, and thus, has excellent adhesiveness, heat resistance, and flexibility, so that the semiconductor device can be suitably used in personal computers, smartphones, wearable devices, and flexible devices, for example.

The order of layering members in the semiconductor device is not particularly limited, and may be appropriately selected according to a purpose. The semiconductor, the adhesion layer, and the intermediate layer may each be formed by one layer, or may be formed by a plurality of layers.

### <Adhesion Layer>

The adhesion layer is preferably a die bonding layer formed between the substrate and the semiconductor or between one of the semiconductors and another one of the semiconductors. In general, the linear expansion coefficient of the semiconductor is about 3 ppm/K, and the linear expansion coefficient of the substrate has often a high value, such as 15 ppm/K or more. Thus, thermal stress is generated by a manufacturing process step such as reflow and a heat cycle due to drive heat, so that adhesion and connection failures easily occur in the semiconductor. On the other hand, in the above-described semiconductor device, if the adhesion layer is a die bonding layer formed between the substrate and the semiconductor, the semiconductor and the substrate have different linear expansion coefficients, so that, even when thermal stress occurs due to the heat cycle or when the semiconductor device is used in a high-temperature environment of 100° C. or higher, the semiconductor device has the advantage that adhesion and connection failures are less likely to occur. Further, as for the resistance of the semiconductor device in the reflow step, good adhesive strength is obtained in terms of shear adhesive strength (die shear strength) when the semiconductor device is heated to about 260° C.

Specifically, the die shear strength at 260° C. when an adhesion target of the adhesive structure has a square shape having a length of 5.0 mm, a width of 5.0 mm, and a thickness of 0.4 mm is not particularly limited, and may be appropriately selected according to a purpose, but is preferably 40 N or more, and more preferably 50 N or more. The die shear strength of the adhesive structure is preferably 40 N or more, because in this case, the adhesive structure has heat resistance and adhesiveness, and a heat dissipation effect can be imparted to the adhesive structure.

Further, if the semiconductor device includes a heat-generating component other than the semiconductor and the cooling component, the adhesion layer is preferably a heat dissipation layer formed between the heat-generating component and the cooling component.

<Heat-Generating Component other than Semiconductor>

The heat-generating component other than the semiconductor is not particularly limited and may be appropriately selected according to a purpose. Examples of the heat-generating component include, but are not limited to, a battery, an LED, a capacitor, a resistor, and a diode.

### <Cooling Component, Substrate, and Electrode>

The cooling component, the substrate, and the electrode are not particularly limited and may be appropriately selected according to a purpose. Examples thereof include, but are not limited to, components similar to those described as the adhesion target.

### <Intermediate Layer>

Examples of the intermediate layer include, but are not limited to, a heat diffusion layer that diffuses heat in the planar direction and a surface treatment layer that improves adhesiveness.

### <<Heat Diffusion Layer>>

The heat diffusion layer is an intermediate layer that diffuses heat in the planar direction. A material for forming the heat diffusion layer is not particularly limited and may be appropriately selected according to a purpose. However, the material preferably contains materials having good thermal conductivity such as metals (Ag, Cu, Au, Al, and the like), carbon, and ceramics (SiO₂, Al₂O₃, AlN, MgO₂, BN, and the like).

The thickness of the heat diffusion layer is not particularly limited, and can be appropriately optimized according to the heat dissipation design and the like.

If a metal material such as the above-described metal (Ag, Cu, Au, Al, and the like) is formed into a film under vacuum, the thickness of the heat diffusion layer is preferably 0.05 μm or more and 10 μm or less.

If the carbon material such as carbon nanoparticle ink or graphene ink is used to form a coating, the thickness of the heat diffusion layer is preferably 1 μm or more and 300 μm or less.

If the ceramic material is applied as a ceramic paste obtained by mixing ceramic particles and a resin, the thickness of the heat diffusion layer is preferably 1 μm or more and 500 μm or less.

The method of forming a film of the metal material under vacuum is not particularly limited and may be appropriately selected according to a purpose. Examples of the method include, but are not limited to, vacuum vapor deposition, a sputtering method, an ion plating method, and chemical vapor deposition (CVD). Each of these methods may be used alone or in combination with others. Among these methods, the sputtering method allows film formation at high speed, and thus is preferable as the method of forming a film of the metal material under vacuum.

A wet film forming method of forming a film of the carbon material and the ceramic material is not particularly limited and may be appropriately selected according to a purpose. Examples of the method include, but are not limited to, a plating method.

The coating method using the carbon nanoparticle ink or the graphene ink and the coating method using the ceramic paste are not particularly limited and may be appropriately selected according to a purpose. Examples of the coating methods include, but are not limited to, a spin coating method, a casting method, a micro gravure coating method, a gravure coating method, a bar coating method, a roll coating method, a wire bar coating method, a dip coating method, a slit coating method, a capillary coating method, a spray coating method, a nozzle coating method, a dispense coating method, and various types of printing methods such as a gravure printing method, a screen printing method, a flexographic printing method, an offset printing method, a reverse printing method, and an inkjet printing method.

### <<Surface Treatment Layer>>

The surface treatment layer is an intermediate layer that improves adhesiveness. The surface treatment layer is formed as a layer that adjusts wettability or surface energy of the film surface, and is formed as a resin film having a hydrophilic group or a hydrophobic group on the surface.

The material forming the surface treatment layer is not particularly limited and may be appropriately selected according to a purpose. Examples of the material include, but are not limited to, a material including a carboxyl group, an amino group, a keto group, an OH-group, a fluorine group, or a silanol group in a resin structure.

The material for forming the surface treatment layer may contain inorganic particles such as other metals of the resin material (such as Ag, Cu, Au, and Al), carbon, and ceramics (such as SiO₂, Al₂O₃, AlN, MgO₂, and BN).

The thickness of the surface treatment layer is not particularly limited, but is preferably in a range of 0.5 μm or more and 10 μm or less.

The method of forming the surface treatment layer is not particularly limited and may be appropriately selected according to a purpose. For example, the surface treatment layer may be formed as follows. A coating of a mixture of an organic monomer material having at least a reactive group and a resin material or an inorganic material to which an initiator is mixed is applied. Subsequently, the applied coating is cured by a curing process such as UV irradiation, a heat treatment, and a dehydration treatment.

Examples of the method of applying the surface treatment layer include, but are not limited to, a spin coating method, a casting method, a micro gravure coating method, a gravure coating method, a bar coating method, a roll coating method, a wire bar coating method, a dip coating method, a slit coating method, a capillary coating method, a spray coating method, a nozzle coating method, a dispense coating method, and various types of printing methods such as a gravure printing method, a screen printing method, a flexographic printing method, an offset printing method, a reverse printing method, and an inkjet printing method.

Next, the semiconductor device of the present embodiment will be described in detail with reference to the drawings, but the semiconductor device of the present embodiment is not limited to this configuration.

As described above, the adhesive structure of the semiconductor device contains the resin including the glycidylamine-type epoxy unit and the oxetane unit, and the component derived from the cationic polymerization initiator. The proportion of the glycidylamine-type epoxy unit in the resin is 10% by mass or more. The constitution requirements of the adhesive structure are as described above in the heading (Method of Manufacturing Adhesive Structure).

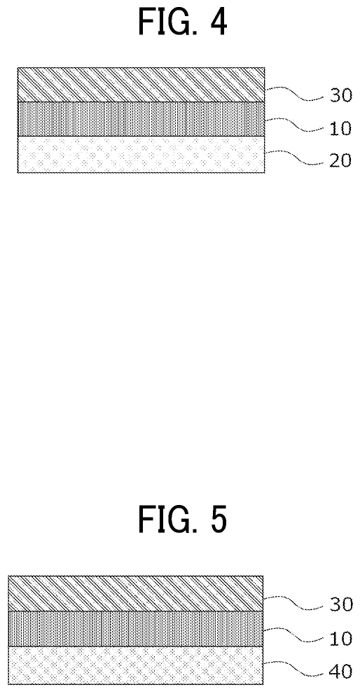

FIG. 4 is a schematic cross-sectional view illustrating Configuration Example 1 of a semiconductor device using the adhesive structure (adhesion layer) of the present embodiment. In FIG. 4, the adhesion layer 10 is adhered to a heat-generating component 30 and a substrate 20. Here, the heat-generating component 30 is a semiconductor (die) or a semiconductor package. The adhesion layer 10 withstands stress caused by the difference in linear expansion coefficients between the heat-generating component 30 and the substrate 20, and maintains adhesiveness even when the temperature changes.

FIG. 5 is a schematic cross-sectional view illustrating Configuration Example 2 of a semiconductor device using the adhesive structure (adhesion layer) of the present embodiment. FIG. 5 differs from Configuration Example 1 in that, instead of the substrate 20, a cooling component 40 is adhered to the adhesion layer 10. The cooling component 40 is a component that cools the heat of the heat-generating component 30 by air cooling, liquid cooling, phase-change cooling, or thermoelectric cooling, for example.

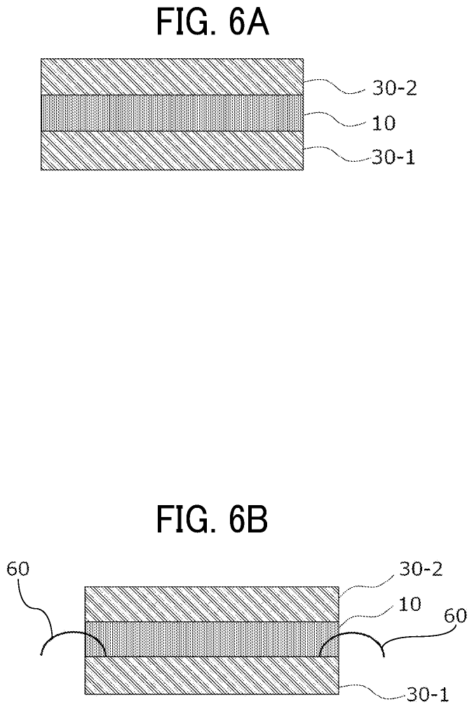

FIGS. 6A and 6B are schematic cross-sectional views illustrating Configuration Example 3 of a semiconductor device using the adhesive structure (adhesion layer) of the present embodiment. FIGS. 6A and 6B differ from Configuration Example 1 in that another heat-generating component 30-2 is adhered to a heat-generating component 30-1 via the adhesion layer 10. The configuration aspects of FIGS. 6A and 6B are useful for laminating heat-generating components and for reducing a temperature difference between 30-1 and 30-2 to obtain a uniform temperature. FIG. 6B is an example where the heat-generating component is a semiconductor (die) and is wire-bonded from a top surface of the heat-generating component 30-1 with a wiring part 60.

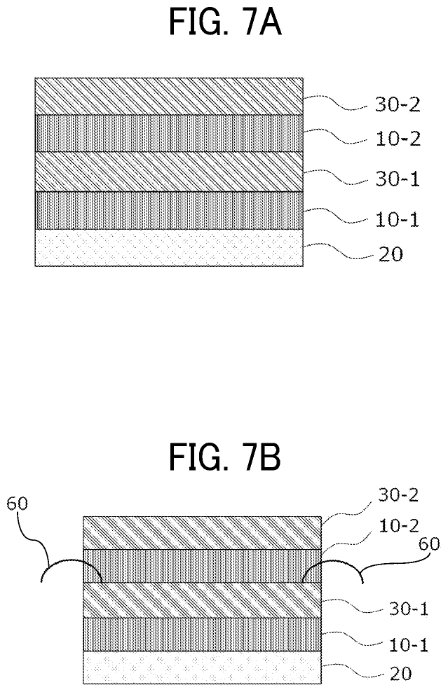

FIGS. 7A and 7B are schematic cross-sectional views illustrating Configuration Example 4 of a semiconductor device using the adhesive structure (adhesion layer) of the present embodiment. FIGS. 7A and 7B differ from Configuration Example 1 in that the other heat-generating component 30-2 is adhered to the heat-generating component 30-1 via another adhesion layer 10-2 and further, the heat-generating component 30-1 and the substrate 20 are adhered to each other via an adhesion layer 10-1. FIG. 7B is an example where the heat-generating component is a semiconductor (die) and is wire-bonded from the top surface of the heat-generating component 30-1 with the wiring part 60.

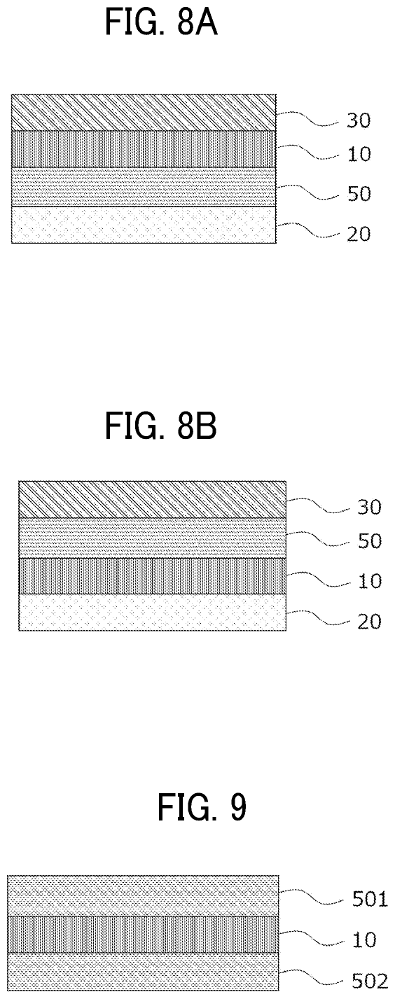

FIGS. 8A and 8B illustrate Configuration Example 5 of a semiconductor device using the adhesive structure (adhesion layer) of the present embodiment. FIG. 8A differs from Configuration Example 1 in that an intermediate layer 50 is formed between the substrate 20 and the adhesion layer 10. FIG. 8B differs from Configuration Example 1 in that the intermediate layer 50 is formed between the heat-generating component 30 and the adhesion layer 10.

The intermediate layer 50 may be formed between the adhesion layer 10 and the substrate 20 and/or between the adhesion layer 10 and the heat-generating component 40. For example, a heat diffusion layer that diffuses heat in the planar direction and a surface treatment layer that improves adhesiveness may be formed.

FIG. 9 is a schematic cross-sectional view illustrating Configuration Example 6 of a semiconductor device using the adhesive structure (adhesion layer) of the present embodiment. FIG. 9 differs from Configuration Example 1 in that an adhesion layer is formed between an electrode 501 and an electrode 502. Configuration Example 6 is effective in a case where electrodes are insulated from each other or in a case where electrodes conduct with each other. As a material for the electrode 501 and the electrode 502, general electrode materials can be used, and specific examples thereof include, but are not limited to, Ag, Cu, Au, Al, Ni, Sn, Pb, mixtures of these materials, and carbon materials. The electrode layers may be divided and patterned as a wiring pattern.

### (Transfer Adhesion Layer)

In a transfer adhesion layer of the present embodiment, the adhesive structure of the present embodiment is formed in a layered shape on a temporary support body.

The adhesive structure of the present embodiment is described above in the heading (Adhesive Structure, Curable Composition for Forming Adhesive Structure, and Method of Manufacturing Adhesive Structure) and thus, detailed description thereof is omitted.

### <Temporary Support Body>

The temporary support body is not particularly limited and a known peeling sheet can be used as the temporary support body, as long as the adhesive structure can be produced on a surface of the temporary support body and the temporary support body does not affect the effect of the adhesive structure.

The peeling sheet is not particularly limited and may be appropriately selected according to a purpose. Examples of the peeling sheet include, but are not limited to, paper such as kraft paper, glassine paper, and woodfree paper; resin films such as polyethylene, polypropylene (oriented polypropylene (OPP), cast polypropylene (CPP)) and polyethylene terephthalate (PET); laminated paper obtained by laminating the above-described types of paper and a resin film; and a product in which the above-described types of paper are subjected to a filling treatment using clay or polyvinyl alcohol and one side or both sides of the treated sheet are subjected to a peeling treatment using a silicone-based resin, for example. Each of these sheets may be used alone or in combination with others.

A method for forming the adhesive structure in a layered shape on the temporary support body is not particularly limited and the method may be similar to the above-described method for manufacturing an adhesive structure, except that the adhesion target is replaced with the temporary support body.

The transfer adhesion layer facilitates storage and transportation of the adhesive structure and is excellent in handleability. The transfer adhesion layer is also advantageous in that, even when it is not possible to directly form the adhesive structure on the adhesion target, the adhesive structure can be easily formed on the adhesion target by attaching the transfer adhesion layer to the adhesion target and peeling off the temporary support body.

### EXAMPLES

Specific examples of the present embodiment will be described below with reference to Preparation Examples, Examples, and Comparative Examples, but the present embodiment is not limited to these Preparation Examples and Examples. In the following Examples and Comparative Examples, the term “parts” refers to “parts by mass” and the term “%” refers to “mass %” unless otherwise specified.

### <Viscosity Measurement Method>

In the following Preparation Examples, a cone rotor (1° 34′×R24) in a cone-plate type rotational viscometer (VISCOMETER TVE-22L, manufactured by Toki Sangyo Co., Ltd.) was used to measure the viscosity of each ink at a number of revolutions of 10 rpm under circulating water having a constant temperature of 25° C. A constant temperature circulating temperature bath (for example, VISCOMATE VM-150III, manufactured by Toki Sangyo Co., Ltd.) was used to adjust the temperature of the circulating water. The results are presented in Tables 3 to 5 below.

### <Method of Measuring Evaporation Amount (Mass Reduction)>

In the following Preparation Examples, the amount of evaporation of each ink was determined by measuring the mass reduction rate up to 300° C. under the following measurement conditions by using a simultaneous differential thermogravimetric analyzer (TG/DTA7200, manufactured by Seiko Instruments (SII) Inc.). The results are presented in Tables 3 to 5 below.

### [Measurement Conditions]

Temperature increase of 10° C./minute, maximum temperature of 520° C., maintained for 5 minutes at maximum temperature
Ink amount: 20 μL

Calculation formula: Ink evaporation amount(mass %)=(initial mass−reduced mass)/initial mass×100

### Preparation Example 1: Preparation of Ink A-1

A heat-curable [ink A-1] was prepared by mixing 15 parts of a glycidylamine-type epoxy compound (TETRAD-X, Mitsubishi Gas Chemical Trading Inc.), 35 parts of an oxetane compound (ARON OXETANE OXT-221, manufactured by Toagosei Co., Ltd.), 35 part of a glycidyl ether-type epoxy compound (HD (D) (manufactured by Yokkaichi Chemical Co., Ltd.), 5 parts of a thermal polymerization initiator (SAN-AID SI-80, manufactured by Sanshin Chemical Industry Co., Ltd.), and 10 parts of inorganic particles (silica particles, primary average particle diameter of 0.5 μm, KE-S50, manufactured by Nippon Shokubai Co., Ltd.).

The viscosity of the [ink A-1] at 25° C. was 80 mPa·s, which was a viscosity suitable for inkjet printing (200 mPa·s or lower).

### Preparation Examples 2 to 13 and 15 to 17: Preparation of Inks A-2 to A-13 and A-15 to A-17

A method similar to the one used in Preparation Example 1, except that the compositions and proportions in Preparation Example 1 were changed to the compositions and proportions illustrated for A-2 to A-13 and A-15 to A-17 in Tables 3 to 5 below, was used to prepare heat-curable [ink A-2] to [ink A-13] and [ink A-15] to [ink A-17] of Preparation Examples 2 to 13 and 15 to 17. The viscosities of [ink A-2] to [ink A-13] and [ink A-15] to [ink A-17] at 25° C. are presented in Tables 3 to 5 below, and except for [ink A-17], the viscosities were suitable for inkjet printing.

The materials used in Preparation Examples 2 to 13 and 15 to 17 and the viscosity characteristics of these materials are presented in Table 2 below.

### Preparation Example 14: Preparation of Ink A-14

A method similar to the method of Preparation Example 1, except that the compositions and proportions in Preparation Example 1 were changed to the composition and the proportion presented in A-14 in Table 5 below, was used to prepare a photo-curable and heat-curable [ink A-14] of Preparation Example 14. The viscosity of the [ink A-14] at 25° C. is presented in Table 5 below and the viscosity was suitable for inkjet printing.

The materials used in Preparation Example 14 and the viscosity characteristics of these materials are presented in Table 2 below.

### Preparation Examples 18 to 22: Preparation of Inks B-1 to B-5

A method similar to the method of Preparation Example 1, except that the compositions and proportions in Preparation Example 1 were changed to the compositions and proportions presented in B-1 to B-5 in Table 6 below, was used to prepare heat-curable [ink B-1] to [ink B-5] used as comparative ink in Preparation Examples 18 to 22. The viscosities of [ink B-1] to [ink B-5] at 25° C. are illustrated in Table 6 below and the viscosities were suitable for inkjet printing.

The materials used in Preparation Examples 18 to 22 and the viscosity characteristics of these materials are presented in Table 2 below.

TABLE 2

| | | Granularity |
|---|---|---|
| Material | Product name | [mPa · s] |
| Glycidylamine-type epoxy | TETRAD-X | 1,600-2,500 |
| compound | EP-3950S | 650 |
| | ELM-434VL | 5,000 |
| Oxetane Compound | OXT-221 | 9-14 |
| | OXT-121 | 150-185 |
| Alicyclic epoxy compound | THI-DE | 20 |
| | CEL8010 | 60 |
| | DE-103 | Solid body |
| Glycidyl ether-type epoxy | HD(D) | 9.81 |
| compound | PETG | 133.5 |
| Oxetane acrylate | OXE-10 | 4.3 |
| Acrylate | A-DPH | 7,500 |
| Thermal cationic | SI-100 | Solid body |
| polymerization initiator | SI-80 | Solid body |
| | SI-60 | Solid body |
| Inorganic particles (silica | KE-S50 | Solid body |
| particles) | | |
| Primary particle diameter | | |
| 0.5 μm | | |
| Organic particles | MG-651 | Solid body |
| Primary particle diameter | | |
| 0.15 μm | | |
| Photo-radical | IRGACURE TPO | Solid body |
| polymerization initiator | | |

The structural formulas of the materials listed in Table 2 are illustrated below.

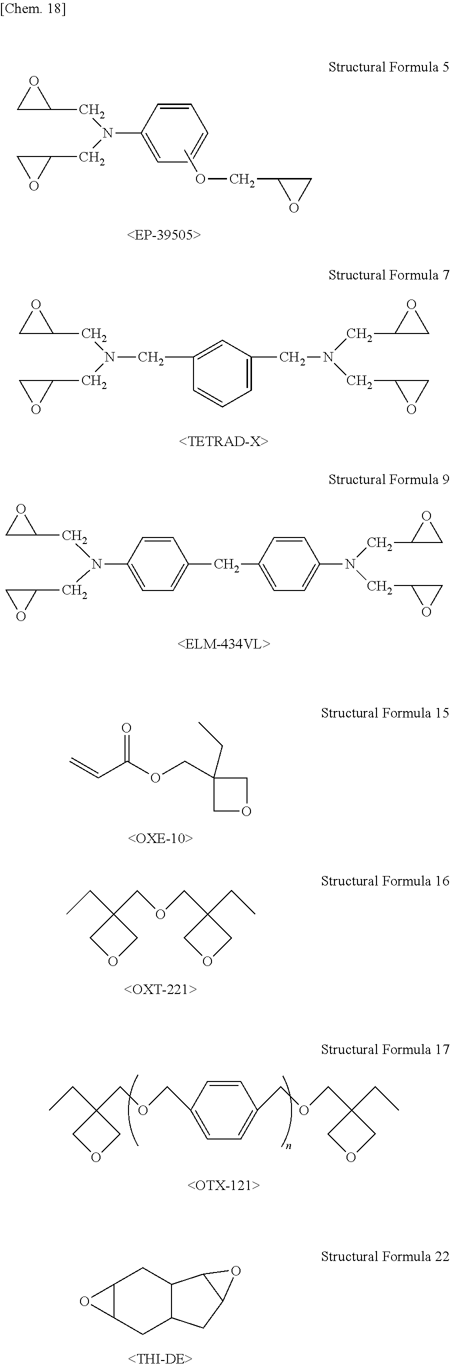

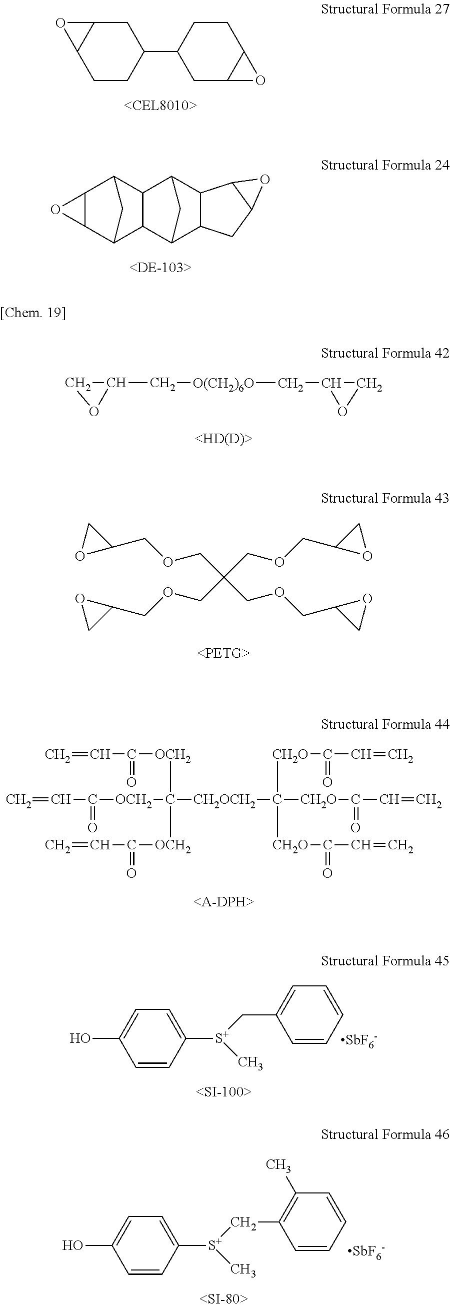

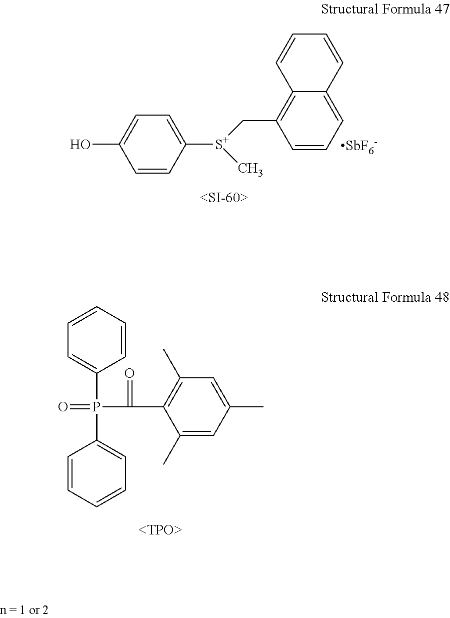

TABLE 3

| | | Preparation | Preparation | Preparation | Preparation | Preparation | Preparation |
|---|---|---|---|---|---|---|---|
| | Product | Example 1 | Example 2 | Example 3 | Example 4 | Example 5 | Example 6 |
| Material | name | A-1 | A-2 | A-3 | A-4 | A-5 | A-6 |
| Glycidylamine- | TETRAD-X | 15 | 15 | 15 | 20 | 20 | 30 |
| type epoxy | EP-3950S | — | — | — | — | — | — |
| compound | ELM- | — | — | — | — | — | — |
| | 434VL | | | | | | |
| Oxetane | OXT-221 | 35 | — | 35 | 35 | 50 | 30 |
| Compound | OXT-121 | — | 35 | — | — | — | — |
| Alicyclic epoxy | THI-DE | — | — | — | — | — | — |
| compound | CEL8010 | — | — | — | — | — | — |
| | DE-103 | — | — | — | — | — | — |
| Glycidyl ether- | HD(D) | 35 | 35 | 35 | 40 | 17 | 30 |
| type epoxy | | | | | | | |
| compound | PETG | — | — | — | — | 10 | — |
| Oxetane | OXE-10 | — | — | — | — | — | — |
| acrylate | | | | | | | |
| Acrylate | A-DPH | — | — | — | — | — | — |
| Thermal | SI-100 | — | — | — | — | — | 10 |
| cationic | SI-80 | 5 | 5 | 5 | 5 | 3 | — |
| polymerization | SI-60 | — | — | — | — | — | — |
| initiator | | | | | | | |
| Inorganic | KE-S50 | 10 | 10 | — | — | — | — |
| particles (silica | | | | | | | |
| particles) | | | | | | | |
| Primary | | | | | | | |
| particle | | | | | | | |
| diameter 0.5 | | | | | | | |
| μm | | | | | | | |
| Organic | MG-651 | — | — | 10 | — | — | — |
| particles | | | | | | | |
| Primary | | | | | | | |
| particle | | | | | | | |
| diameter 0.15 | | | | | | | |
| μm | | | | | | | |
| Photo-radical | IRGACURE | — | — | — | — | — | — |
| polymerization | TPO | | | | | | |
| initiator | | | | | | | |
| Total [parts by mass] | | 100 | 100 | 100 | 100 | 100 | 100 |
| Ink | Viscosity | 80 | 150 | 160 | 30 | 60 | 70 |
| characteristics | [mPa · s] | | | | | | |
| | Evaporation | 0 | 0 | 0 | 0 | 0 | 0 |
| | amount | | | | | | |
| | [mass %] | | | | | | |

TABLE 4

| | | Preparation | Preparation | Preparation | Preparation | Preparation | Preparation |
|---|---|---|---|---|---|---|---|
| | Product | Example 7 | Example 8 | Example 9 | Example 10 | Example 11 | Example 12 |
| Material | name | A-7 | A-8 | A-9 | A-10 | A-11 | A-12 |
| Glycidylamine- | TETRAD-X | — | — | 10 | 10 | 20 | 20 |
| type epoxy | EP-3950S | 20 | — | — | — | — | — |
| compound | ELM- | — | 20 | — | — | — | — |
| | 434VL | | | | | | |
| Oxetane | OXT-221 | 20 | 20 | 10 | 60 | 20 | 20 |
| Compound | OXT-121 | — | — | — | — | — | — |
| Alicyclic | THI-DE | — | — | — | — | 20 | — |
| epoxy | CEL8010 | — | — | — | — | — | 20 |
| compound | DE-103 | — | — | 15 | — | — | — |
| Glycidyl ether- | HD(D) | — | — | 20 | — | 35 | 35 |
| type epoxy | | | | | | | |
| compound | PETG | 45 | 45 | 40 | 29 | — | — |
| Oxetane | OXE-10 | — | — | — | — | — | — |
| acrylate | | | | | | | |
| Acrylate | A-DPH | — | — | — | — | — | — |
| Thermal | SI-100 | — | — | — | — | — | — |
| cationic | | | | | | | |
| polymerization | SI-80 | 5 | 5 | 5 | 1 | 5 | 5 |
| initiator | SI-60 | — | — | — | — | — | — |
| Inorganic | KE-S50 | 10 | 10 | — | — | — | — |
| particles (silica | | | | | | | |
| particles) | | | | | | | |
| Primary | | | | | | | |
| particle | | | | | | | |
| diameter 0.5 | | | | | | | |
| μm | | | | | | | |
| Organic | MG-651 | — | — | — | — | — | — |
| particles | | | | | | | |
| Primary | | | | | | | |
| particle | | | | | | | |
| diameter 0.15 | | | | | | | |
| μm | | | | | | | |
| Photo-radical | IRGACURE | — | — | — | — | — | — |
| polymerization | TPO | | | | | | |
| initiator | | | | | | | |
| Total [parts by mass] | | 100 | 100 | 100 | 100 | 100 | 100 |
| Ink | Viscosity | 200 | 200 | 180 | 30 | 50 | 70 |
| characteristics | [mPa · s] | | | | | | |
| | Evaporation | 5 | 5 | 5 | 0 | 5 | 5 |
| | amount | | | | | | |
| | [mass %] | | | | | | |

TABLE 5

| | | Preparation | Preparation | Preparation | Preparation | Preparation |
|---|---|---|---|---|---|---|
| | | Example 13 | Example 14 | Example 15 | Example 16 | Example 17 |
| Material | Product name | A-13 | A-14 | A-15 | A-16 | A-17 |
| Glycidylamine- | TETRAD-X | 20 | 15 | — | 20 | 30 |
| type epoxy | EP-3950S | — | — | 40 | — | — |
| compound | ELM-434VL | — | — | — | — | — |
| Oxetane | OXT-221 | — | 20 | 30 | 10 | — |
| Compound | OXT-121 | 40 | — | — | — | 30 |
| Alicyclic | THI-DE | — | — | — | — | — |
| epoxy | CEL8010 | — | — | — | — | — |
| compound | DE-103 | — | — | — | — | — |
| Glycidyl ether- | HD(D) | 35 | 20 | 25 | 50 | 20 |
| type epoxy | | | | | | |
| compound | PETG | — | 20 | — | — | — |
| Oxetane | OXE-10 | — | 16 | — | — | — |
| acrylate | | | | | | |
| Acrylate | A-DPH | — | 4 | — | — | — |
| Thermal | SI-100 | — | — | 5 | — | 10 |
| cationic | | | | | | |
| polymerization | SI-80 | 5 | — | — | 10 | — |
| initiator | SI-60 | — | 4 | — | — | — |
| Inorganic | KE-S50 | — | — | — | 10 | 10 |
| particles (silica | | | | | | |
| particles) | | | | | | |
| Primary | | | | | | |
| particle | | | | | | |
| diameter 0.5 | | | | | | |
| μm | | | | | | |
| Organic | MG-651 | — | — | — | — | — |
| particles | | | | | | |
| Primary | | | | | | |
| particle | | | | | | |
| diameter 0.15 | | | | | | |
| μm | | | | | | |
| Photo-radical | IRGACURE | — | — | — | — | — |
| polymerization | TPO | | | | | |
| initiator | | | | | | |
| Total [parts by mass] | | 100 | 100 | 100 | 100 | 100 |
| Ink | Viscosity | 60 | 30 | 50 | 80 | 500 |
| characteristics | [mPa · s] | | | | | |
| | Evaporation | 0 | 5 | 0 | 5 | 0 |
| | amount | | | | | |
| | [mass %] | | | | | |

TABLE 6

| | | Preparation | Preparation | Preparation | Preparation | Preparation |
|---|---|---|---|---|---|---|
| | | Example 18 | Example 19 | Example 20 | Example 21 | Example 22 |
| Material | Product name | B-1 | B-2 | B-3 | B-4 | B-5 |
| Glycidylamine- | TETRAD-X | — | — | — | 5 | 20 |
| type epoxy | EP-3950S | — | — | — | — | — |
| compound | ELM-434VL | — | — | — | — | — |
| Oxetane | OXT-221 | — | — | 99 | 30 | — |
| Compound | OXT-121 | — | — | — | — | — |
| Alicyclic | THI-DE | 99 | — | — | — | 70 |
| epoxy | CEL8010 | — | — | — | — | — |
| compound | DE-103 | — | — | — | 30 | — |
| Glycidyl ether- | HD(D) | — | 99 | — | 30 | — |
| type epoxy | | | | | | |
| compound | PETG | — | — | — | — | — |
| Oxetane | OXE-10 | — | — | — | — | — |
| acrylate | | | | | | |
| Acrylate | A-DPH | — | — | — | — | — |
| Thermal | SI-100 | — | — | — | — | — |
| cationic | | | | | | |
| polymerization | SI-80 | 1 | 1 | 1 | 5 | 10 |
| initiator | SI-60 | — | — | — | — | — |
| Inorganic | KE-S50 | — | — | — | — | — |
| particles (silica | | | | | | |
| particles) | | | | | | |
| Primary | | | | | | |
| particle | | | | | | |
| diameter 0.5 | | | | | | |
| μm | | | | | | |
| Organic | MG-651 | — | — | — | — | — |
| particles | | | | | | |
| Primary | | | | | | |
| particle | | | | | | |
| diameter 0.15 | | | | | | |
| μm | | | | | | |
| Photo-radical | IRGACURE | — | — | — | — | — |
| polymerization | TPO | | | | | |
| initiator | | | | | | |
| Total [parts by mass] | | 100 | 100 | 100 | 100 | 100 |
| Ink | Viscosity | 20 | 15 | 20 | 70 | 90 |
| characteristics | [mPa · s] | | | | | |
| | Evaporation | 30 | 20 | 0 | 0 | 60 |
| | amount | | | | | |
| | [mass %] | | | | | |

In the [ink A-1] to [ink A-17] that contain a glycidylamine-type epoxy compound, an oxetane compound, and a cationic polymerization initiator, the evaporation amount of ink (that is, the amount of ink reduction) was 5% by mass or less, and the evaporation of ink during heat-curing was suppressed. On the other hand, in the [ink B-1], the [ink B-2], and the [ink B-5], which are comparative inks not containing the oxetane compound, the evaporation amount of ink was large. If the evaporation amount of ink is large, it is difficult to control the film thickness, and the composition of a non-evaporating component (that is, the cured product) changes, so that it is difficult to use the ink as a heat-curable composition for forming an adhesive structure.

### <Measurement of Indentation Elastic Modulus of Cured Film>

The [ink A-1] to [ink A-17] obtained in Preparation Examples 1 to 22 and the [ink B-1] to [ink B-5] used as comparative inks were cured by a method described below and the indentation elastic modulus of measurement samples of the cured products was measured by a method described below.

### —Preparation of Measurement Sample—

The [ink A-1] to [ink A-17] obtained in Preparation Examples 1 to 22 and the [ink B-1] to [ink B-5], which are comparative inks, were respectively used to prepare measurement samples as follows. The inks were applied by dispense coating to a glass surface having a thickness of 1 mm. In the glass having a thickness of 1 mm, a fluororesin (PTFE) tape was attached to the glass so that the PTFE tape contacts a printing surface of the ink. The glass was heated at 100° C. for 2 hours, was further heated at 200° C. for 1 hour, and then, was further heated and cured at 260° C. for 5 minutes. After that, the glass having a thickness of 1 mm and to which the PTFE tape was attached was peeled to prepare the measurement samples in which a cured film having a thickness of 15 μm was formed on the surface of the glass having a thickness of 1 mm. The film thickness of the cured film was adjusted by the coating amount of the ink.

The photocurable and heat-curable [ink A-14] was photocured with a UV LED (365 nm) using a HONLE LED CUBE 100 (manufactured by Honle UV Technology) before heat curing, and then, the photocurable and heat-curable [ink A-14] was heat-cured.

### —Measurement of Indentation Elastic Modulus—

The indentation elastic modulus of the measurement samples prepared by the above-described method were measured by using a microhardness tester (FISCHERSCOPE (registered trademark) HM2000, manufactured by Fischer Instruments Co., Ltd.) under the following measurement conditions. The measurement results of the indentation elastic modulus of each measurement sample are illustrated in Table 4 below.

### [Measurement Conditions]

Indenter: Vickers indenter
Maximum load: 10 mN
Maximum indentation depth: 1 μm
Loading (unloading) time: 40 sec

### Example 1

In Example 1, a laminated sample having the configuration illustrated in FIGS. 1A and 1B was prepared.

A substrate for a printed wiring board (BGA) as the substrate 300 and a silicon chip substrate as a heat-generating component 200 were prepared and adhered to the adhesion layer 10 to form a laminated sample.

When forming the adhesion layer 10, an inkjet device (manufactured by Cluster Technology Co., Ltd.) having a nozzle hole diameter of 60 μm was used.

The specific method was as follows.

### <Preparation of Laminated Sample by Adhesion Layer>

### —Preparation of Substrate—

A ball grid array (BGA) substrate (may be referred to as “BGA substrate” hereinafter) including a core material/copper wiring/solder resist having a square shape with a length of 10 mm, a width of 10 mm, and a thickness of 0.28 mm was prepared. The linear expansion coefficient of the BGA substrate was 14 ppm/K.

### —Design—

An adhesion layer forming region having a square shape with four sides of 5.0 mm was designed at a center of the BGA substrate in the planar direction. The design was such that the center of the adhesion layer forming region and the center of the BGA substrate coincided with each other.

### —Formation of Adhesion Part—

The [ink A-1] prepared in Preparation Example 1 was used as the adhesion part forming ink, and inkjet printing was performed in the adhesion layer forming region having a square shape with four sides of 5.0 mm to form the adhesion part. At this time, the droplet amount of the [ink A-1] was controlled to obtain an average thickness of 15 μm. Thus, the adhesion layer 10 including the adhesion part 1 was formed on the BGA substrate, as illustrated in FIGS. 1A and 1B.

### —Lamination of Substrates—

Next, the silicon chip substrate 200 having a square shape with a length of 5.0 mm, a width of 5.0 mm, and a thickness of 0.4 mm was laminated onto the surface of the adhesion layer opposite to the surface of the adhesion layer 10 contacting the BGA substrate 300. After that, the substrate was heated at 100° C. for 2 hours, was further heated at 200° C. for 1 hour, and then, was further heated and cured at 260° C. for 5 minutes, to prepare a laminated sample having the configuration illustrated in FIGS. 1A and 1B in which the adhesion layer of Example 1, in which the BGA substrate 300 and the silicon chip substrate 200 are laminated by the adhesive layer 10, was used. The linear expansion coefficient of the silicon chip substrate was 3.34 ppm/K.

The average thickness of the adhesion layer is an average value of the thickness measured at any three locations of the adhesion layer with a stylus meter (ALPHA-STEP D-500, manufactured by KLA-Tenchore).

### Examples 2 to 4 and 8 to 17

Laminated samples were prepared by using the adhesion layers of Examples 2 to 4 and 8 to 17 in a method similar to Example 1, except that the [ink A-1] as the adhesion part forming ink in Example 1 was replaced with any one of the [ink A-2] to [ink A-4] and the [ink A-8] to [ink A-17] presented in Table 7 below.

When forming the adhesion layer 10, ink having an ink viscosity of 30 mPa·s or less was applied by using an inkjet device (STAGE JET, manufactured by Tritek Co., Ltd.) including an MH5420 (manufactured by Ricoh Co., Ltd.) as an inkjet head. Ink having an ink viscosity of 50 mPa-s or more was used with an inkjet device (manufactured by Cluster Technology Co., Ltd.) having a nozzle hole diameter of 60 km.

### Examples 5 to 7

Laminated samples were prepared by using the adhesion layers of Examples 5 to 7 in a method similar to Example 1, except that the [ink A-1] as the adhesion part forming ink in Example 1 was replaced with any one of [ink A-5] to [ink A-7] listed in Table 7 below, and the average thickness of 15 μm obtained in Example 1 by controlling the droplet amount of ink was changed to the average thickness values listed in Table 7 below obtained by controlling the droplet amount of ink.

### Example 18

The laminated sample of Example 18 was prepared by a method similar to Example 1, except that the adhesion layer including only the adhesion part 1 of Example 1 illustrated in FIGS. 1A and 1B was changed to the adhesion layer including the adhesion part 1 and the pattern adjusting part 2 illustrated in FIGS. 2A and 2B.

That is, the same BGA substrate and the same silicon chip substrate as in Example 1 were used.

Specifically, the laminated sample was prepared by a method similar to Example 1, except that the “Design”, “Formation of Adhesion Part”, and “Lamination of Substrates” in Example 1 were changed as described below, and the “Formation of Pattern Adjusting Part” was performed as described below.

### —Design—

As illustrated in FIG. 2B, an adhesion layer forming region having a square shape with four sides of 5.0 mm was designed at a center of the BGA substrate in the planar direction. The design was such that the center of the adhesion layer forming region and the center of the BGA substrate coincided with each other. In the adhesion layer forming region, a pattern adjusting part forming region was designed to have a width of 0.5 mm surrounding an adhesion part forming region having a square shape with four sides of 4.0 mm. The design was such that the center of the adhesion layer forming region and the center of the adhesion part forming region coincided with each other.

### —Formation of Pattern Adjusting Part—

In Example 18, the photocurable and heat-curable [ink A-14] prepared in Preparation Example 14 was used as a pattern adjusting ink.

The [ink A-14] was used to print in the pattern adjusting part forming region on the BGA substrate by inkjet printing, based on the design. At this time, the droplet amount of the [ink A-14] was controlled to form a pattern adjusting part having an average thickness of 15 μm and a width of 0.5 mm. Next, deposited droplets of the discharged [ink A-14] were photocured by a UV LED (365 nm) using a HONLE LED Cube 100 (manufactured by Honle UV Technology), to suppress wet spreading of the deposited droplets. Thus, the volume of the pattern adjusting part was 50% by volume or less of the volume of the adhesion layer 10.

### —Formation of Adhesion Part—

Next, the [ink A-1] prepared in Preparation Example 1 was used as the adhesion part forming ink, to form the adhesion part by performing inkjet printing, based on the design, in the adhesion part forming region having a square shape with four sides of 4.0 mm inside the pattern adjusting part formed on the BGA substrate. At this time, the droplet amount of the [ink A-1] was controlled to obtain an average thickness of 15 μm. Thus, the adhesion layer 10 including the adhesion part 1 and the pattern adjusting part 2 was formed on the BGA substrate, as illustrated in FIGS. 2A and 2B.

### —Lamination of Substrates—

Next, the silicon chip substrate 200 having a square shape with a length of 5.0 mm, a width of 5.0 mm, and a thickness of 0.4 mm was laminated onto the surface of the adhesion layer opposite to the surface of the adhesion layer 10 contacting the BGA substrate 300. After that, the substrate was heated at 100° C. for 2 hours, was further heated at 200° C. for 1 hour, and then, was further heated and cured at 260° C. for 5 minutes, to prepare a laminated sample having the configuration illustrated in FIGS. 2A and 2B in which the adhesion layer of Example 18, in which the BGA substrate 300 and the silicon chip substrate 200 are laminated by the adhesive layer 10, was used.

### Example 19

A laminated sample having the configuration illustrated in FIGS. 2A and 2B in which the adhesion layer of Example 19 is used, was manufactured by using a method similar to Example 18, except that the [ink A-1] used as the adhesion part forming ink in Example 18 was changed to the [ink A-4] prepared in Preparation Example 4, and instead of using an inkjet device (manufactured by Cluster Technology Co., Ltd., having a nozzle hole diameter of 60 μm) as the inkjet device for forming the adhesion layer 10, an inkjet device (STAGE JET, manufactured by Tritek Co., Ltd.) including an MH5420 (manufactured by Ricoh Co., Ltd.) as an inkjet head was used.

### Example 20

A laminated sample having the configuration illustrated in FIGS. 2A and 2B in which the adhesion layer of Example 20 is used, was manufactured by using a method similar to Example 18, except that the [ink A-1] as the adhesion part forming ink in Example 18 was changed to the [ink A-6] prepared in Preparation Example 6, and the average thickness of 15 m obtained in Example 18 by controlling the droplet amount of ink was changed to an average thickness of 20 μm by controlling the droplet amount of ink. A film thickness of 20 m was used.

### Comparative Example 1

A laminated sample of Comparative Example 1 was prepared by a method similar to Example 1, except that the [ink A-1] used as the adhesion part forming ink in Example 1 was changed to the [ink B-1] that was prepared in Preparation Example 18 and does not include the glycidylamine-type epoxy compound and the oxetane compound, and instead of using an inkjet device (manufactured by Cluster Technology Co., Ltd., having a nozzle hole diameter of 60 μm) as the inkjet device for forming the adhesion layer 10, an inkjet device (STAGE JET, manufactured by Tritek Co., Ltd.) including an MH5420 (manufactured by Ricoh Co., Ltd.) as an inkjet head was used.

### Comparative Example 2

A laminated sample of Comparative Example 2 was prepared by a method similar to Example 1, except that the [ink A-1] used as the adhesion part forming ink in Example 1 was changed to the [ink B-2] that was prepared in Preparation Example 19 and does not include the glycidylamine-type epoxy compound and the oxetane compound, and instead of using an inkjet device (manufactured by Cluster Technology Co., Ltd., having a nozzle hole diameter of 60 μm) as the inkjet device for forming the adhesion layer 10, an inkjet device (STAGE JET, manufactured by Tritek Co., Ltd.) including an MH5420 (manufactured by Ricoh Co., Ltd.) as an inkjet head was used.

### Comparative Example 3

A laminated sample of Comparative Example 3 was prepared by a method similar to Example 1, except that the [ink A-1] used as the adhesion part forming ink in Example 1 was changed to the [ink B-3] that was prepared in Preparation Example 20 and does not include the glycidylamine-type epoxy compound, and instead of using an inkjet device (manufactured by Cluster Technology Co., Ltd., having a nozzle hole diameter of 60 μm) as the inkjet device for forming the adhesion layer 10, an inkjet device (STAGE JET, manufactured by Tritek Co., Ltd.) including an MH5420 (manufactured by Ricoh Co., Ltd.) as an inkjet head was used.

### Comparative Example 4

A laminated sample of Comparative Example 4 was prepared by a method similar to Example 1, except that the [ink A-1] used as the adhesion part forming ink in Example 1 was changed to the [ink B-4] that was prepared in Preparation Example 21 and in which the proportion of the glycidylamine-type epoxy compound was 5%.

### Comparative Example 5

A laminated sample of Comparative Example 5 was prepared by a method similar to Example 1, except that the [ink A-1] used as the adhesion part forming ink in Example 1 was changed to the [ink B-5] that was prepared in Preparation Example 22 and does not include the oxetane compound.

### <Measurement of Die Shear Strength>

To evaluate the adhesive strength of the samples of Examples 1 to 20 and Comparative Examples 1 to 5 in a heated state, the shear strength (the die shear strength) at 260° C. was evaluated by the following method.

The shear adhesive strength (die shear strength) of the laminated samples of Examples 1 to 20 and Comparative Examples 1 to 5 at 260° C. was evaluated by a bond tester (DAGE 4000, Nordson Corporation). The measurement conditions were conform with JEITA standard ED-4703 K-111. The results are presented in Table 7 below.

TABLE 7

| | Adhesion part forming ink | | | | | | Pattern | |
|---|---|---|---|---|---|---|---|---|
| | | Proportion of | | Adhesion part | | | adjusting | |
| | | glycidylamine- | Proportion | Average | Average | | part | Evaluation |
| | | type epoxy | of oxetane | thickness | thickness | Elastic | forming | Die shear |
| | | compound | compound | (uncured) | (cured) | modulus | ink | strength |
| | Type | [mass %] | [mass %] | [μm] | [μm] | [Mpa] | Type | [N] |
| Example 1 | A-1 | 15 | 35 | 15 | 15 | 3887.7 | none | 122.7 |
| Example 2 | A-2 | 15 | 35 | 15 | 15 | 3631.2 | none | 115.1 |
| Example 3 | A-3 | 15 | 35 | 15 | 15 | 1028.7 | none | 82.2 |
| Example 4 | A-4 | 20 | 35 | 15 | 15 | 2096.6 | none | 114.9 |
| Example 5 | A-5 | 20 | 50 | 10 | 10 | 1550.0 | none | 142.1 |
| Example 6 | A-6 | 30 | 30 | 20 | 20 | 487.6 | none | 144.2 |
| Example 7 | A-7 | 20 | 20 | 30 | 30 | 2056.1 | none | 59.3 |
| Example 8 | A-8 | 20 | 20 | 15 | 15 | 2904.7 | none | 67.9 |
| Example 9 | A-9 | 10 | 10 | 15 | 15 | 5127.4 | none | 62.1 |
| Example 10 | A-10 | 10 | 60 | 15 | 15 | 2065.2 | none | 51.0 |
| Example 11 | A-11 | 20 | 20 | 15 | 15 | 2492.2 | none | 122.4 |
| Example 12 | A-12 | 20 | 20 | 15 | 15 | 3047.2 | none | 135.1 |
| Example 13 | A-13 | 20 | 40 | 15 | 15 | 509.5 | none | 112.4 |
| Example 14 | A-14 | 15 | 20 | 15 | 15 | 483.9 | none | 62.5 |
| Example 15 | A-15 | 40 | 30 | 15 | 15 | 498.6 | none | 62.0 |
| Example 16 | A-16 | 20 | 10 | 15 | 15 | 2941.5 | none | 138.1 |
| Example 17 | A-17 | 30 | 30 | 15 | 15 | 1031.6 | none | 150.8 |
| Example 18 | A-1 | 15 | 35 | 15 | 15 | 3887.7 | A-14 | 132.2 |
| Example 19 | A-4 | 20 | 35 | 15 | 15 | 2096.6 | A-14 | 120.1 |
| Example 20 | A-6 | 30 | 30 | 20 | 20 | 487.6 | A-14 | 110.2 |
| Comparative | B-1 | 0 | 0 | 15 | 15 | 8683.0 | none | below 6 |
| Example 1 | | | | | | | | |
| Comparative | B-2 | 0 | 0 | 15 | 15 | 306.6 | none | below 6 |
| Example 2 | | | | | | | | |
| Comparative | B-3 | 0 | 99 | 15 | 15 | 98.6 | none | below 6 |
| Example 3 | | | | | | | | |
| Comparative | B-4 | 5 | 30 | 15 | 15 | 1949.1 | none | 30.1 |
| Example 4 | | | | | | | | |
| Comparative | B-5 | 20 | 0 | 15 | 5 | 986.4 | none | 83.6 |
| Example 5 | | | | | | | | |

The results in Table 7 indicated that the die shear strength in Examples 1 to 20 was 50 N or more, and good adhesive strength and heat resistance were confirmed. On the other hand, in Comparative Examples 1, 2, and 3, the die shear strength was below the lower measurement limit (6.0 N). In Comparative Example 4, the die shear strength was 30.1 N, which was lower than in the Examples. In Comparative Example 5, the ink was applied so that the average thickness of the adhesion part was 15 μm. However, after forming (curing) the adhesion part, it was found that the average thickness was 5 μm, which was considerably thinner than the thickness of 15 μm before curing, and thus, it was difficult to form the adhesion part according to the design.

In Table 7, the proportions (mass %) of the glycidylamine-type epoxy compound and the oxetane compound indicate the proportion in the curable composition for forming an adhesive structure that was used to form the adhesion layer.

Examples of aspects of the present embodiment include, but are not limited to, the aspects below.
<1> A curable composition for forming an adhesive structure according to a first aspect is a curable composition for forming an adhesive structure that is discharged by an inkjet printing method, and the curable includes
   a glycidylamine-type epoxy compound, an oxetane compound, and a cationic polymerization initiator, in which a proportion of the glycidylamine-type epoxy compound is 10% by mass or more.
<2> According to a second aspect, in the curable composition for forming an adhesive structure according to the first aspect, a proportion of the oxetane compound is 10% by mass or more and 60% by mass or less.
<3> According to a third aspect, in the curable composition for forming an adhesive structure according to any one of the first aspect and the second aspect, a proportion of the cationic polymerization initiator is 1% by mass or more and 10% by mass or less.
<4> According to a fourth aspect, in the curable composition for forming an adhesive structure according to any one of the first to third aspects, the glycidylamine-type epoxy compound is trifunctional or higher functional.
<5> According to a fifth aspect, the curable composition for forming an adhesive structure according to any one of the first to fourth aspects has a viscosity of 200 mPa-s or less at 25° C.
<6> According to a sixth aspect, the curable composition for forming an adhesive structure according to any one of the first to fifth aspects further includes at least one of inorganic particles having a primary average particle diameter (D50) of 0.1 μm or more and 5 μm or less and resin particles having a primary average particle diameter (D50) of 0.1 μm or more and 5 μm or less.
<7> A cured product according to a seventh aspect is obtained by curing the curable composition for forming an adhesive structure according to any one of the first to sixth aspects.
<8> An adhesive structure according to an eighth aspect includes a resin including a glycidylamine-type epoxy unit and an oxetane unit, and a component derived from a cationic polymerization initiator, and
   a proportion of the glycidylamine-type epoxy unit in the resin is 10% by mass or more.
<9> According to a ninth aspect, in the adhesive structure according to the eighth aspect, a proportion of the oxetane unit in the resin is 10% by mass or more and 60% by mass or less.
<10> According to a tenth aspect, the adhesive structure according to any one of the eighth aspect and the ninth aspect has an elastic modulus of 500 MPa or more and 5,000 MPa or less.
<11> According to an eleventh aspect, in the adhesive structure according to any one of the eighth to tenth aspects, the adhesive structure has a thickness of 1 μm or more and 30 μm or less.
<12> According to a twelfth aspect, the adhesive structure according to any one of the eighth to eleventh aspects includes an adhesion part including the resin including the glycidylamine-type epoxy unit and the oxetane unit, and the component derived from the cationic polymerization initiator, and a pattern adjusting part including a photocurable resin.
<13> According to a thirteenth aspect, in the adhesive structure according to the twelfth aspect, a volume of the pattern adjusting part is 50% by volume or less of a volume of the adhesion part.
<14> According to a fourteenth aspect, the adhesive structure according to any one of the eighth to thirteenth aspects further includes a heat conducting part formed continuously in a thickness direction.
<15> According to a fifteenth aspect, the adhesive structure according to any one of the eighth to fourteenth aspects demonstrates a die shear strength of 50 N or more at 260° C. with respect to an adhesion target having a square shape having a length of 5.0 mm, a width of 5.0 mm, and a thickness of 0.4 mm.
<16> A semiconductor device according to a sixteenth aspect includes a semiconductor, an adhesion layer, and a substrate, in which the adhesion layer includes the adhesive structure according to any one of the eighth to fifteenth aspects.
<17> According to a seventeenth aspect, in the semiconductor device according to the sixteenth aspect, the adhesion layer is a die bonding layer formed between the substrate and the semiconductor or between one of the semiconductors and another one of the semiconductors.
<18> According to an eighteenth aspect, in the semiconductor device according to any one of the sixteenth aspect and the seventeenth aspect, the semiconductor device further includes a heat-generating component and a cooling component, and the adhesion layer is a heat dissipation layer formed between the heat-generating component and the cooling component.
<19> A method of manufacturing an adhesive structure according to a nineteenth aspect, the method including using the curable composition for forming an adhesive structure according to any one of the first to sixth aspects.
<20> A method of manufacturing a semiconductor device according to a twentieth aspect, the method including:
   a pattern adjusting part forming step of forming a pattern adjusting part on a substrate by pattern-forming using a pattern adjusting part forming composition including a monomer of a photocurable resin, and
   an adhesion part forming step of forming an adhesion part to be adjacent to the pattern adjusting part by using the curable composition for forming an adhesive structure according to any one of the first to sixth aspects.

According to the curable composition for forming an adhesive structure according to any one of the first to sixth aspects, the cured product according to the seventh aspect, the adhesive structure according to any one of the eighth to fifteenth aspects, the semiconductor device according to any one of the sixteenth to eighteenth aspects, the method of manufacturing an adhesive structure according to the nineteenth aspect, and the method of manufacturing a semiconductor device according to the twentieth aspect, it is possible to solve various conventional problems and achieve the object of the present embodiment.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Any one of the above-described operations may be performed in various other ways, for example, in an order different from the one described above.

This patent application is based on and claims priority to Japanese Patent Application Nos. 2022-097962 and 2023-068473, filed on Jun. 17, 2022 and Apr. 19, 2023, respectively, in the Japan Patent Office, the entire disclosure of each of which is hereby incorporated by reference herein.

### REFERENCE SIGNS LIST

1 Adhesion part
2 Pattern adjusting part
3 Heat conducting part
10 Adhesion layer
10-1 Adhesion layer
10-2 Adhesion layer
20 Substrate
30 Heat-generating component
30-1 Heat-generating component
30-2 Heat-generating component
40 Cooling component
50 Intermediate layer
60 Wiring part
200 Silicon chip substrate
300 Substrate for printed wiring board (BGA)
501 Electrode
502 Electrode

1: A curable composition for forming an adhesive structure for discharge by an inkjet printing method, the curable composition comprising:
a glycidylamine-type epoxy compound;
an oxetane compound; and
a cationic polymerization initiator,
wherein a proportion of the glycidylamine-type epoxy compound in the curable composition is 10% by mass or more.

2: The curable composition for forming an adhesive structure according to claim 1, wherein:
a proportion of the oxetane compound in the curable composition is 10% by mass or more and 60% by mass or less.

3: The curable composition for forming an adhesive structure according to claim 1, wherein:
a proportion of the cationic polymerization initiator in the curable composition is 1% by mass or more and 10% by mass or less.

4: The curable composition for forming an adhesive structure according to claim 1, wherein:
the glycidylamine-type epoxy compound is trifunctional or higher functional.

5: The curable composition for forming an adhesive structure according to claim 1, wherein:
the curable composition has a viscosity of 200 mPa·s or less at 25° C.

6: The curable composition for forming an adhesive structure according to claim 1, further comprising:
at least one of inorganic particles having a primary average particle diameter (D50) of 0.1 μm or more and 5 μm or less and resin particles having a primary average particle diameter (D50) of 0.1 μm or more and 5 μm or less.

7: An adhesive structure, comprising:
a resin including a glycidylamine-type epoxy unit and an oxetane unit; and
a component derived from a cationic polymerization initiator,
wherein a proportion of the glycidylamine-type epoxy unit in the resin is 10% by mass or more.

8: The adhesive structure according to claim 7, wherein:
the adhesive structure has an elastic modulus of 500 MPa or more and 5,000 MPa or less.

9: The adhesive structure according to claim 7, wherein:
the adhesive structure has a thickness of 1 μm or more and 30 μm or less.

10: The adhesive structure according to claim 7, further comprising:
an adhesion section including the resin including the glycidylamine-type epoxy unit and the oxetane unit, and the component derived from the cationic polymerization initiator; and
a pattern adjusting section including a photocurable resin.

11: The adhesive structure according to claim 10, wherein:
a volume of the pattern adjusting part is 50% by volume or less of a volume of the adhesive structure.

12: The adhesive structure according to claim 11, further comprising:
a heat conducting part formed continuously in a thickness direction.

13: The adhesive structure according to claim 7, wherein:
the adhesive structure demonstrates a die shear strength of 50 N or more at 260° C. with respect to an adhesion target having a square shape having a length of 5.0 mm, a width of 5.0 mm, and a thickness of 0.4 mm.

14: A semiconductor device, comprising:
a semiconductor;
an adhesion layer; and
a substrate,
wherein the adhesion layer includes the adhesive structure according to claim 7.

15: A method of manufacturing an adhesive structure, the method comprising using the curable composition for forming an adhesive structure according to claim 1.
